(19) United States
(12) Patent Application Publication
(10) Pub. No.: US 2025/0275410 A1
(43) Pub. Date: Aug. 28, 2025

(54) DISPLAY DEVICE AND ELECTRONIC DEVICE INCLUDING THE SAME

(71) Applicant: Samsung Display Co., LTD., Yongin-si (KR)

(72) Inventors: Sun Kwun SON, Yongin-si (KR); Dong Hee SHIN, Yongin-si (KR); Tae Hyun KIM, Yongin-si (KR); Jung Suk BANG, Yongin-si (KR); Na Hyeon CHA, Yongin-si (KR)

(21) Appl. No.: 18/954,326

(22) Filed: Nov. 20, 2024

(30) Foreign Application Priority Data
Feb. 22, 2024 (KR) 10-2024-0026082

(51) Int. Cl. H10K 59/35; H10K 59/131

(52) U.S. Cl. CPC H10K 59/352; H10K 59/131

(57) ABSTRACT

A display device includes a display area including unit pixels each including a first emission area, a second emission area, and a third emission area, a first unit pixel of the unit pixels in a first column of the display area, and a second unit pixel of the unit pixels in a second column of the display area and adjacent to the first unit pixel in a first direction, wherein at a first edge portion at one end of the first unit pixel in a second direction, only the first emission area and the second emission area are positioned, and at a second edge portion adjacent to the first edge portion in the first direction and at one end of the second unit pixel in the second direction, the first emission area, the second emission area, and the third emission area of the second unit pixel are positioned.

### CROSS-REFERENCE TO RELATED APPLICATION

The present application claims priority to and the benefit of Korean Patent Application No. 10-2024-0026082, filed on Feb. 22, 2024, in the Korean Intellectual Property Office, the entire content of which is incorporated herein by reference.

### BACKGROUND

### 1. Field

Embodiments of the present disclosure relate to a display device and an electronic device including the display device.

### 2. Description of the Related Art

As information technology develops, the demand for display devices for displaying images has increased and diversified. That is, with the advancement of information society technology, the demand for image display devices has grown and diversified. Accordingly, one or more suitable types (kinds) of display devices including light emitting display devices have been developed.

A display device may include pixels emitting light of different colors. For example, the display device may include red pixels emitting red light, green pixels emitting green light, and blue pixels emitting blue light. Accordingly, the display device may display a full-color image.

### SUMMARY

Aspects of one or more embodiments of the present disclosure are directed toward a display device capable of improving image quality by preventing or reducing a color fringing or color jamming phenomenon while improving light emitting areas or aperture ratios of pixels, and an electronic device including the display device.

However, aspects of the present disclosure are not limited to the ones set forth herein. Additional aspects will be set forth in part in the description which follows and, in part, will be apparent from the description, or may be learned by practice of the presented embodiments of the disclosure.

According to one or more embodiments of the present disclosure, a display device includes a display area including unit pixels each including a first emission area, a second emission area, and a third emission area, a first unit pixel of the unit pixels in a first column of the display area, and a second unit pixel of the unit pixels in a second column of the display area and adjacent to the first unit pixel in a first direction, wherein at a first edge portion at one end of the first unit pixel in a second direction crossing the first direction, only the first emission area and the second emission area of the first emission area, the second emission area, and the third emission area of the first unit pixel are positioned, and at a second edge portion adjacent to the first edge portion in the first direction and at one end of the second unit pixel in the second direction, the first emission area, the second emission area, and the third emission area of the second unit pixel are positioned.

In one or more embodiments, at a third edge portion at an opposite end of the first unit pixel relative to the one end of the first unit pixel in the second direction, the first emission area, the second emission area, and the third emission area of the first unit pixel may be arranged.

In one or more embodiments, the first column of the display area may include a first pad electrode at the first edge portion.

In one or more embodiments, each of the unit pixels may include a first pixel electrode in the first emission area, a second pixel electrode in the second emission area, and a third pixel electrode in the third emission area, and the first pad electrode may be between the first pixel electrode and the second pixel electrode of the first unit pixel at the first edge portion.

In one or more embodiments, the first pad electrode may overlap the first emission area and the second emission area of the first unit pixel at the first edge portion.

In one or more embodiments, a size of the third emission area may be smaller than a size of each of the first emission area and the second emission area, and in a unit pixel area of the first unit pixel, the third emission area may be at a position spaced and/or apart (e.g., spaced apart or separated) from the first edge portion.

In one or more embodiments, each of the unit pixels may further include a light emitting layer and a common electrode that are on each of the first pixel electrode, the second pixel electrode, and the third pixel electrode, and the common electrode may be electrically connected to the first pad electrode through a drilling hole at the first pad electrode.

In one or more embodiments, the common electrode may be along an entirety of the display area, and the drilling hole may penetrate through the light emitting layer, on the first pad electrode.

In one or more embodiments, the display device may further include a power line which is electrically connected to the first pad electrode and to which a common voltage is applied.

In one or more embodiments, at a fourth edge portion adjacent to the third edge portion in the first direction and at an opposite end of the second unit pixel relative to the one end of the second unit pixel in the second direction, only the first emission area and the second emission area of the first emission area, the second emission area, and the third emission area of the second unit pixel may be arranged.

In one or more embodiments, the first pixel electrode, the second pixel electrode, and the third pixel electrode of the second unit pixel may be electrically connected to respective pixel circuits through respective connection holes positioned at the fourth edge portion.

In one or more embodiments, the first column of the display area may further include a second pad electrode at the third edge portion.

In one or more embodiments, the second pad electrode may be between the first emission area and the second emission area of the first unit pixel and may overlap the third emission area of the first unit pixel at the third edge portion.

In one or more embodiments, the first column and the second column may include a plurality of unit pixels, and the display area may include a first group of pixel columns which include the first column and in which each first emission area, second emission area, and third emission area have substantially the same structure as the first unit pixel, and a second group of pixel columns which include the second column and in which each first emission area, second emission area, and third emission area have substantially the same structure as the second unit pixel.

In one or more embodiments, the first group of pixel columns may be arranged in the display area every N pixel columns (where N is a natural number of 2 or more), and the second group of pixel columns may be between the first group of pixel columns.

In one or more embodiments, the first group of pixel columns and the second group of pixel columns may be alternately arranged in the display area along the first direction.

In one or more embodiments, the display area may further include a plurality of pad electrodes in the first group of pixel columns.

In one or more embodiments, the second group of pixel columns may not include (e.g., may exclude) the pad electrodes.

In one or more embodiments, the first emission area may be a red emission area emitting red light, the second emission area may be a green emission area emitting green light, and the third emission area may be a blue emission area emitting blue light.

In one or more embodiments, the first direction may be a transverse direction of the display area, and the second direction may be a longitudinal direction of the display area.

According to one or more embodiments of the present disclosure, an electronic device includes a display device. The display device includes a display area including unit pixels each including a first emission area, a second emission area, and a third emission area, a first unit pixel of the unit pixels in a first column of the display area, and a second unit pixel of the unit pixels in a second column of the display area and adjacent to the first unit pixel in a first direction, wherein at a first edge portion at one end of the first unit pixel in a second direction crossing the first direction, only the first emission area and the second emission area of the first emission area, the second emission area, and the third emission area of the first unit pixel are positioned, and at a second edge portion adjacent to the first edge portion in the first direction and at one end of the second unit pixel in the second direction, the first emission area, the second emission area, and the third emission area of the second unit pixel are positioned.

According to one or more embodiments, by efficiently arranging emission areas of unit pixels and pad electrodes in a display area, light emitting areas or aperture ratios of pixels and unit pixels including the pixels may be improved. In one or more embodiments, an edge portion (for example, and upper or lower edge) where only a first emission area and a second emission area of each of the unit pixels are arranged and an edge portion (for example, the other edge of the upper or lower edge) where a first emission area, a second emission area, and a third emission area of each of the unit pixels are arranged, may be staggered or alternately arranged. For example, a second edge portion where a first emission area, a second emission area, and a third emission area of a second unit pixel are arranged may be arranged on one side of a first edge portion where only a first emission area and a second emission area of a first unit pixel are arranged. Accordingly, image quality of a display device may be improved by preventing or reducing a color fringing or color jamming phenomenon that may occur at upper edge portions, lower edge portions, and/or the like, of pixel rows.

However, effects according to one or more embodiments of the present disclosure are not limited to those enumerated above and one or more suitable other effects may be incorporated herein.

### BRIEF DESCRIPTION OF THE DRAWINGS

The above and other aspects, features, and/or principles of one or more embodiments of the present disclosure will become more apparent by describing in more detail embodiments thereof with reference to the attached drawings, in which:

FIG. 1 is a plan view illustrating a display device according to one or more embodiments of the present disclosure;

FIG. 2 is a plan view illustrating a display panel of FIG. 1, according to one or more embodiments of the present disclosure;

FIG. 3 is a circuit diagram illustrating a pixel according to one or more embodiments of the present disclosure;

FIG. 4 is a plan view illustrating a portion of a display area according to one or more embodiments of the present disclosure;

FIG. 5 is a cross-sectional view illustrating a portion of a display panel taken along the line X1-X1′, according to one or more embodiments of the present disclosure;

FIG. 6 is a cross-sectional view illustrating a portion of the display panel taken along the line X2-X2′, according to one or more embodiments of the present disclosure;

FIG. 7 is a cross-sectional view illustrating a portion of the display panel taken along the line X3-X3′, according to one or more embodiments of the present disclosure;

FIG. 8 is an enlarged view of area A1 of FIG. 5, according to one or more embodiments of the present disclosure;

FIG. 9 is a plan view illustrating a portion of a display area according to one or more embodiments of the present disclosure; and

FIG. 10 is a plan view illustrating a portion of a display area according to one or more embodiments of the present disclosure.

### DETAILED DESCRIPTION

The present disclosure may be modified in many alternate forms, and thus specific embodiments will be illustrated in the drawings and described in more detail. It should be understood, however, that this is not intended to limit the present disclosure to the particular forms disclosed, but rather, is intended to cover all modifications, equivalents, and alternatives falling within the spirit and scope of the present disclosure.

Hereinafter, example embodiments will be described in more detail with reference to the accompanying drawings. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described.

It will be understood that when an element, such as an area, layer, film, region or portion, is referred to as being “on,” “connected to,” or “coupled to” another element, it can be directly on, connected to, or coupled to the other element, or one or more intervening elements may be present. In addition, it will also be understood that when an element is referred to as being “between” two elements, it can be the only element between the two elements, or one or more intervening elements may also be present.

Unless otherwise noted, like reference numerals denote like elements throughout the attached drawings and the written description, and thus, duplicative descriptions thereof may not be provided.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

Features of each of various embodiments of the present disclosure may be partially or entirely combined with each other and may technically variously interwork with each other, and respective embodiments may be implemented independently of each other or may be implemented together in association with each other.

Spatially relative terms, such as “on,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the drawings. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

The terminology used herein is for the purpose of describing particular embodiments only and is not intended to be limiting of the present disclosure. As used herein, the singular forms “a,” “an” and “the” are intended to include the plural forms as well, unless the context clearly indicates otherwise. It will be further understood that the terms “comprises,” “comprising,” “includes,” “including,” “have,” and “having,” when used in this specification, specify the presence of the stated features, integers, steps, operations, elements, and/or components, but do not preclude the presence or addition of one or more other features, integers, steps, operations, elements, components, and/or groups thereof.

As used herein, the term “and/or” includes any and all combinations of one or more of the associated listed items. Unless otherwise apparent from the disclosure, expressions such as “at least one of,” “a plurality of,” “one of,” and other prepositional phrases, when preceding a list of elements, should be understood as including the disjunctive if written as a conjunctive list and vice versa. For example, the expressions “at least one of a, b, or c,” “at least one of a, b, and/or c,” “one selected from the group consisting of a, b, and c,” “at least one selected from among a, b, and c,” “at least one from among a, b, and c,” “one from among a, b, and c”, “at least one of a to c” indicates only a, only b, only c, both a and b, both a and c, both b and c, all of a, b, and c, or variations thereof.

As used herein, the terms “use,” “using,” and “used” may be considered synonymous with the terms “utilize,” “utilizing,” and “utilized,” respectively.

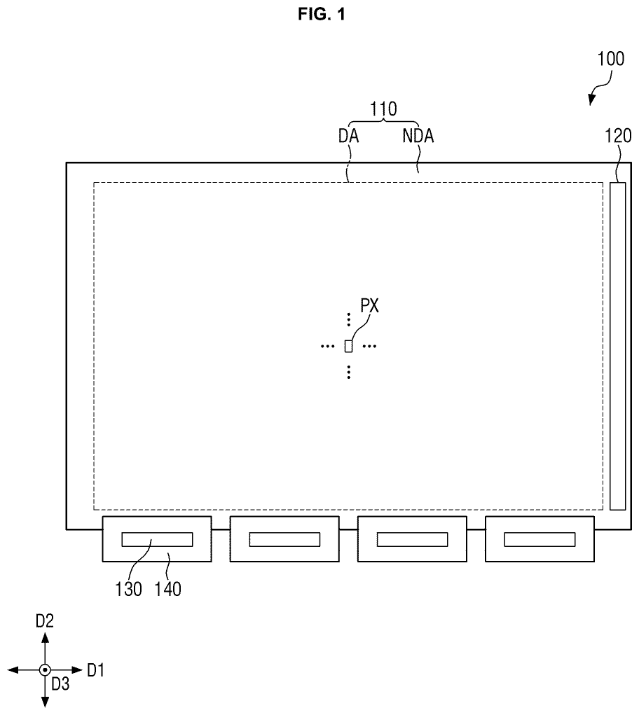

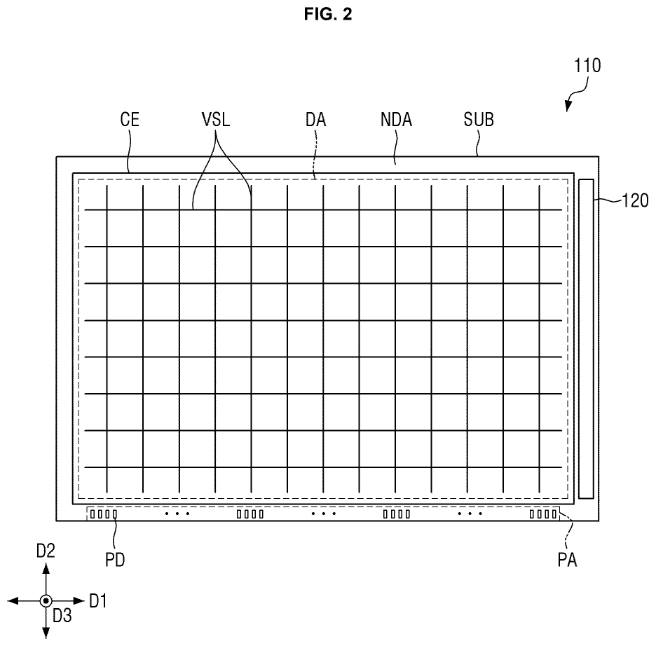

FIG. 1 is a plan view illustrating a display device 100 according to one or more embodiments of the present disclosure. FIG. 2 is a plan view illustrating a display panel 110 of FIG. 1, according to one or more embodiments of the present disclosure.

Referring to FIGS. 1 and 2, the display device 100 is a device that displays a moving image and/or a still image, and may be used as a display screen of one or more suitable products such as televisions, laptop computers, monitors, billboards, and the Internet of Things (IOT), as well as portable electronic devices such as mobile phones, smartphones, tablet personal computers (PCs), smart watches, watch phones, mobile communication terminals, electronic notebooks, electronic books, portable multimedia players (PMPs), navigation devices, and ultra mobile PCs (UMPCs). Such electronic devices are only examples, and the display device 100 may also be adopted in other electronic devices.

In one or more embodiments, the display device 100 may be a light emitting display device such as an organic light emitting display device including organic light emitting diodes, a quantum dot light emitting display device including quantum dot light emitting layers, an inorganic light emitting display device including inorganic semiconductors, or a micro light emitting display device including micro light emitting diodes such as micro or nano light emitting diodes (micro LEDs or nano LEDs), but the present disclosure is not limited thereto. For example, the display device 100 may also be a type or kind of display device other than the light emitting display device. Hereinafter, embodiments in which the display device 100 is a light emitting display device (e.g., an organic light emitting display device) will be disclosed.

The display device 100 may include a display panel 110 including pixels PX, and a first driver 120 and a second driver 130 supplying driving signals to the pixels PX. The display device 100 may further include additional components. For example, the display device 100 may further include a power supply unit for supplying source voltages to the pixels PX, the first driver 120, and the second driver 130, a timing controller for controlling operations of the first driver 120 and the second driver 130, and/or the like.

The display panel 110 may include a display area DA and a non-display area NDA. The display area DA may be an area displaying an image by including the pixels PX. For example, the display area DA may include pixel areas where the respective pixels PX are arranged (e.g., positioned). The non-display area NDA is an area other than the display area DA, and an image may not be displayed in the non-display area NDA. In one or more embodiments, the non-display area NDA may be positioned around the display area DA, and may be around (e.g., surround) the display area DA.

In FIGS. 1 and 2, a first direction D1, a second direction D2, and a third direction D3 are defined. In one or more embodiments, the first direction D1 may be a transverse direction of the display panel 110 (or the display area DA), and the second direction D2 may be a longitudinal direction of the display panel 110 (or the display area DA). The third direction D3 may be a thickness direction of the display panel 110.

In one or more embodiments, the display panel 110 may have a rectangular shape in a plan view. It has been illustrated in FIGS. 1 and 2 that the display panel 110 has a shape in which a transverse length is greater than a longitudinal length, but a shape of the display panel 110 is not limited thereto. For example, the display panel 110 may have a shape in which the longitudinal length is greater than the transverse length or the display panel 110 may have a square shape, and/or the like. The display panel 110 may include angled corners or rounded corners.

The shape of the display panel 110 in a plan view is not limited to the illustrated rectangular shape, and may also be other shapes. For example, the display panel 110 may have a non-rectangular polygonal shape, a circular shape, an elliptical shape, an irregular shape, or other shapes in a plan view.

In one or more embodiments, the display panel 110 may be substantially flat on a plane (e.g., in a plan view) defined by the first direction D1 and the second direction D2, and may have a substantially uniform thickness in the third direction D3. In one or more embodiments, the display panel 110 may be provided in a three-dimensional shape having a curved surface and/or the like.

The display panel 110 may be provided as a rigid panel so as not to be substantially deformed or may be provided as a flexible panel so as to be deformed, for example, folded, bent, or rolled, in at least a portion thereof. The display panel 110 may be provided in the display device 100 in a state in which it is not bent, or may be provided in the display device 100 in a state in which it is bent in a part or section thereof.

The display panel 110 may include a substrate SUB (e.g., a lower substrate) and pixels PX may be arranged on the substrate SUB. The pixels PX may be arranged in a display area DA on the substrate SUB.

The substrate SUB is a base member for manufacturing or providing the display panel 110, and may constitute a base surface of the display panel 110. The substrate SUB may include a display area DA and a non-display area NDA arranged around the display area DA.

The display area DA may have one or more suitable shapes according to one or more embodiments. For example, the display area DA may a rectangular shape, a non-rectangular polygonal shape, a circular shape, an elliptical shape, an irregular shape, or other shapes. In one or more embodiments, the display area DA may have a shape matching the shape of the display panel 110.

The pixels PX may be provided and/or arranged in the display area DA. For example, the display area DA may include a plurality of pixel areas where the respective pixels PX are arranged. Each pixel area may include an emission area where light is emitted from each pixel PX.

In one or more embodiments, the display device 100 may be a light emitting display device, and each pixel PX may include a light emitting element positioned in each emission area and a pixel circuit connected to the light emitting element. In describing embodiments, the term “connection” may include an electrical connection and/or a physical connection. Each pixel circuit may include transistors (e.g., transistors including a driving transistor generating a driving current corresponding to a data signal and at least one switching transistor) and at least one capacitor (e.g., a storage capacitor).

Lines connected to the pixels PX may be further provided in the display area DA. For example, the display area DA may include signal lines and power lines connected to the pixels PX. The signal lines and the power lines may extend to the non-display area NDA to be connected to the first driver 120 or the respective pads PD. As an example, some of the signal lines may be connected to the first driver 120 to transfer scan signals, control signals, and/or the like that are output from the first driver 120 to the pixels PX, and the others of the signal lines may be connected to the second driver 130 through the respective pads PD to transfer data signals output from the second driver 130 to the pixels PX. The power lines may be connected to the respective pads PD to transfer pixel voltages supplied from the power supply unit and/or the like via circuit boards 140 and/or the like to the pixels PX.

In FIG. 2, a second power line VSL connected to a common electrode CE has been illustrated as an example of the lines that may be arranged in the display area DA. In one or more embodiments, the common electrode CE may be one electrode (e.g., a cathode electrode) of light emitting elements provided in the pixels PX, and may be entirely formed in the display area DA. In one or more embodiments, the common electrode CE may have a shape and/or a size corresponding to the display area DA, and may extend to the outside of the display area DA while having an area greater than or equal to that of the display area DA.

In one or more embodiments, the second power line VSL may be provided in a panel circuit layer located below a light emitting element layer in which the common electrode CE is arranged. The second power line VSL and the common electrode CE may be electrically connected to each other through a plurality of pad electrodes arranged in the display area DA.

The second power line VSL may be connected to at least one pad PD (e.g., a power pad supplying a common voltage) positioned in a pad area PA. For example, the second power line VSL may extend from the display area DA to the non-display area NDA to be directly connected to the at least one pad PD or be connected to at least one pad PD through a connection line formed in the non-display area NDA.

In one or more embodiments, the second power line VSL may include a low-resistance conductive material. By supplying the common voltage to the common electrode CE through the second power line VSL, a voltage drop in the common voltage may be prevented, reduced, and/or minimized. Accordingly, a luminance change due to the voltage drop in the common voltage may be prevented or reduced, and image quality of the display device 100 may be improved.

In one or more embodiments, the second power line VSL may be a mesh-type or kind line arranged in a mesh form in the display area DA, but the present disclosure is not limited thereto. For example, depending on a design space securable in the display area DA, a position, form, size, and/or the like of the second power line VSL may be variously changed. As an example, the second power line VSL may include only transverse lines extending in the first direction D1 in the display area DA or include only longitudinal lines extending in the second direction D2 in the display area DA.

The non-display area NDA may include the pad area PA where the pads PD are arranged. In one or more embodiments, the non-display area NDA may further include a driving circuit area positioned on at least one side of the display area DA. At least one driver, pads PD, lines, and/or the like may be arranged in the non-display area NDA.

The pads PD may be arranged in the pad area PA. At least one circuit board 140 may be arranged on and/or bonded onto the pad area PA. In one or more embodiments, a plurality of circuit boards 140 connected to different pads PD may be arranged on the pad area PA. The pads PD may include signal pads and power pads for transferring driving signals and source voltages desired or required for driving the pixels PX and/or the first driver 120 at the inside of the display panel 110.

The first driver 120 and the second driver 130 may generate driving signals for controlling operation timings, luminance, and/or the like of the pixels PX, and may supply the driving signals to the pixels PX. For example, the first driver 120 may be a gate driver including a scan driver, and may be connected to the pixels PX through the respective gate lines (e.g., scan lines and/or control lines). The first driver 120 may supply the respective gate signals (e.g., control signals for controlling driving timings of the pixels PX, including scan signals and/or control signals) to the pixels PX. The second driver 130 may be a data driver including source driving circuits, and may be connected to the pixels PX through the respective data lines. The second driver 130 may supply the respective data signals to the pixels PX.

In one or more embodiments, at least one of the first driver 120 and/or the second driver 130 or a portion of the at least one driver may be embedded in the display panel 110. For example, the first driver 120 or a portion of the first driver 120 may be arranged on the substrate SUB of the display panel 110 and be arranged and/or formed in the non-display area NDA.

It has been illustrated in FIG. 1 that the first driver 120 is formed in the non-display area NDA on one side of the display area DA (e.g., the right side of the display area DA), but the present disclosure is not limited thereto. For example, the first driver 120 may also be positioned only in the non-display area NDA on the other side of the display area DA (e.g., the left side of the display area DA), or positioned in the non-display areas NDA on both sides (e.g., opposite sides) of the display area DA (e.g., the left side and the right side of the display area DA). In one or more embodiments, a portion of the first driver 120 may be positioned in the non-display area NDA, and the other portion of the first driver 120 may be positioned in a non-emission area (e.g., an area between emission areas of the pixels PX) inside the display area DA.

In one or more embodiments, the other of the first driver 120 and/or the second driver 130 or a portion of the other driver may be arranged or formed outside the display panel 110 and electrically connected to the display panel 110. For example, the second driver 130 may be implemented as a plurality of integrated circuit chips and arranged on the circuit boards 140 electrically connected to the pixels PX of the display panel 110. The second driver 130 may also be implemented as at least one integrated circuit chip and mounted on the non-display area NDA of the display panel 110.

The circuit board 140 may be connected to the display panel 110 through the pads PD. In one or more embodiments, the circuit board 140 may be a flexible printed circuit board (FPCB), a printed circuit board (PCB), or a flexible film such as a chip on film (COF), but the present disclosure is not limited thereto. In one or more embodiments, the circuit board 140 may be connected to the timing controller, the power supply unit, and/or the like, through another circuit board, a connector, and/or the like.

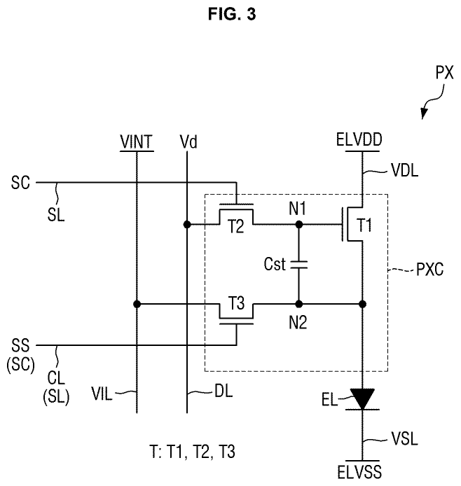

FIG. 3 is a circuit diagram illustrating a pixel PX according to one or more embodiments. For example, FIG. 3 illustrates a pixel PX of a light emitting display device including a light emitting element EL. A type, kind, and/or a structure of the pixel PX that may be included in the display device 100 may be variously changed according to one or more embodiments.

Referring to FIG. 3, the pixel PX may include a light emitting element EL and a pixel circuit PXC connected to the light emitting element EL. The light emitting element EL is a light source of the pixel PX, and may be, for example, an organic light emitting diode, but the present disclosure is not limited thereto. The pixel circuit PXC may control light emission of the light emitting element EL.

The pixel circuit PXC may include transistors T and a capacitor Cst. For example, the pixel circuit PXC may include a first transistor T1, a second transistor T2, a third transistor T3, and a capacitor Cst. An example in which the transistors T are all N-type or kind transistors has been illustrated in FIG. 3, but the types (kinds) of the transistors T are not limited thereto. For example, at least one transistor T may also be formed as a P-type or kind transistor.

The pixel circuit PXC may supply a driving current to the light emitting element EL in response to the driving signals supplied from the first driver 120 and the second driver 130. For example, the pixel circuit PXC may supply the driving current to the light emitting element EL in response to a scan signal SC and a control signal SS supplied from the first driver 120 through a scan line SL and a control line CL and a data signal Vd supplied from the second driver 130 through a data line DL.

An example in which the scan line SL and the control line CL are separated from each other has been illustrated in FIG. 3, but the present disclosure is not limited thereto. For example, the control line CL is a portion of the scan line SL, and may branch from the scan line SL, and the control signal SS may be the scan signal SC.

The first transistor T1 may be a driving transistor of the pixel PX whose magnitude of a drain-source current (e.g., the driving current) is determined according to its gate-source voltage. The second and third transistors T2 and T3 may be switching transistors that are turned on or off depending on their respective gate-source voltages. Depending on a type or kind (e.g., a P-type or kind or N-type or kind transistor) and/or an operation condition of each of the transistors T, a first electrode of each of the transistors T may be a drain electrode (or a drain region) or a source electrode (or a source region), and a second electrode of each of the transistors T may be an electrode different from the first electrode. For example, if (e.g., when) the first electrode is the drain electrode, the second electrode may be the source electrode.

The pixel PX may be connected to the scan line SL transferring the scan signal SC, the control line CL transferring the control signal SS (e.g., a sensing control signal or an initialization control signal), and the data line DL transferring the data signal Vd. In one or more embodiments, the pixel PX may be connected to a first power line VDL transferring a driving voltage ELVDD (also referred to as a “first pixel voltage”) and a second power line VSL transferring a common voltage ELVSS (also referred to as a “second pixel voltage”). A voltage level of the common voltage ELVSS may be lower than a voltage level of the driving voltage ELVDD. In one or more embodiments, the pixel PX may be further connected to an initialization power line VIL transferring an initialization voltage VINT (also referred to as a “third pixel voltage”).

In one or more embodiments, the transistors T may be positioned in each pixel area, and may be oxide transistors each including an oxide semiconductor (also referred to as “oxide semiconductor transistors”). For example, an active layer of each of the first, second, and third transistors T1, T2, and T3 may include an oxide semiconductor. However, the present disclosure is not limited thereto. For example, at least one transistor T may also be made of a semiconductor material (e.g., amorphous silicon or polysilicon) other than the oxide semiconductor.

In one or more embodiments, a light blocking layer, a light blocking electrode, and/or the like, may be arranged below the active layer of at least one of the first, second, and/or third transistors T1, T2, and T3. As an example, a bottom electrode (or a back-gate electrode) blocking external light may be arranged below the active layer of the first transistor T1. Accordingly, operation characteristics of the first transistor T1 may be stabilized.

The first transistor T1 may include a gate electrode connected to a first node N1, a first electrode (e.g., a drain electrode) connected to the first power line VDL, and a second electrode (e.g., a source electrode) connected to a second node N2. The second node N2 may be a node where the pixel circuit PXC and the light emitting element EL are connected to each other. The first transistor T1 may control the driving current of the pixel PX in response to the data signal Vd transferred to the first node N1.

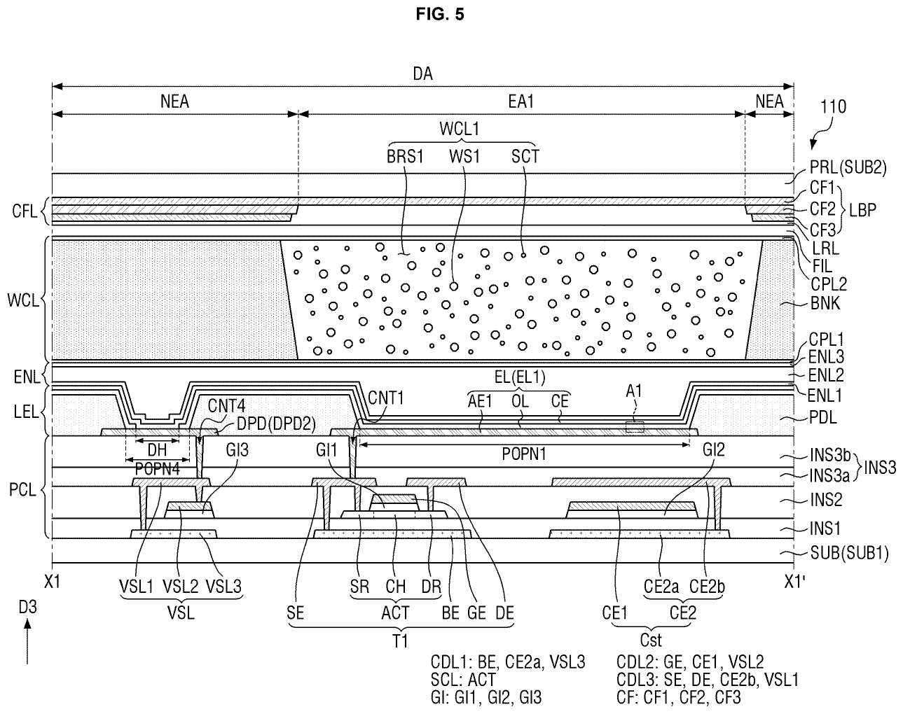

In one or more embodiments, the first transistor T1 may further include a bottom electrode (e.g., a bottom electrode BE in FIG. 5) connected to the second node N2. When the first transistor T1 is formed as a transistor having a double-gate structure (e.g., a double gate transistor having a source-sync structure) by connecting the bottom electrode of the first transistor T1 to the second node N2, operation characteristics of the first transistor T1 may be improved.

The second transistor T2 may include a gate electrode connected to the scan line SL, a first electrode connected to the data line DL, and a second electrode connected to the first node N1. The second transistor T2 may be turned on by the scan signal SC of a gate-on voltage applied to the scan line SL to connect the data line DL and the first node N1 to each other. Accordingly, the data signal Vd applied to the data line DL may be transferred to the first node N1.

The third transistor T3 may include a gate electrode connected to the control line CL (or the scan line SL), a first electrode connected to the second node N2, and a second electrode connected to the initialization voltage line VIL. The third transistor T3 may be turned on by the control signal SS (or the scan signal SC) of a gate-on voltage applied to the control line CL (or the scan line SL) to connect the initialization voltage line VIL and the second node N2 to each other.

The capacitor Cst may be connected between the first node N1 and the second node N2. The capacitor Cst may store a voltage (e.g., a difference voltage between a gate voltage and a source voltage of the first transistor T1) corresponding to the data signal Vd (e.g., a data voltage) transferred to the first node N1.

The light emitting element EL may be connected between the pixel circuit PXC and the second power line VSL. For example, the light emitting element EL may include a pixel electrode (e.g., a first electrode or an anode electrode of the light emitting element EL) connected to the pixel circuit PXC through the second node N2, a common electrode (e.g., a second electrode or a cathode electrode of the light emitting element EL) facing (e.g., opposite to) the first electrode and connected to the second power line VSL, and a light emitting layer interposed between the pixel electrode and the common electrode. In one or more embodiments, the pixel electrode of the light emitting element EL may be provided individually to each pixel PX, and the common electrode of the light emitting element EL may be provided in common to the plurality of pixels PX. The light emitting element EL may be to emit light with luminance corresponding to the driving current during a period in which the driving current is supplied from the pixel circuit PXC.

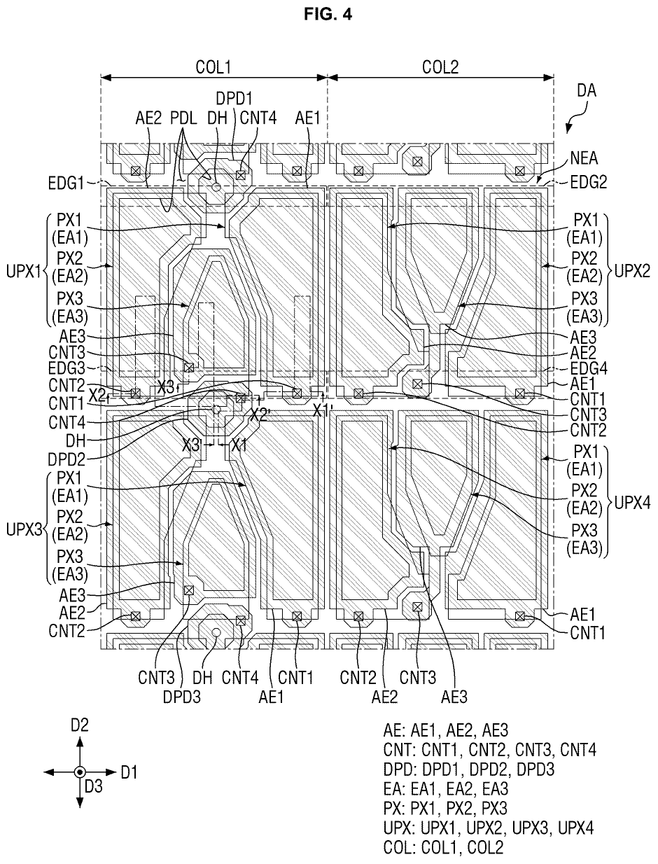

FIG. 4 is a plan view illustrating a portion of a display area DA according to one or more embodiments of the present disclosure. For example, FIG. 4 illustrates a portion of the display area DA where four unit pixels UPX adjacent to each other are arranged.

Referring to FIG. 4, unit pixels UPX may be arranged in the display area DA. In one or more embodiments, the unit pixels UPX may be arranged in a matrix form in the display area DA along the first direction D1 and the second direction D2. For example, the unit pixels UPX may be arranged in pixel columns arranged along the first direction D1 in the display area DA, such as a first column COL1 and a second column COL2. In each pixel column, the unit pixels UPX may be arranged along the second direction D2.

In FIG. 4, on behalf of the unit pixels UPX arranged in the display area DA, a first unit pixel UPX1 and a third unit pixel UPX3 sequentially arranged along the second direction D2 in the first column COL1 and a second unit pixel UPX2 and a fourth unit pixel UPX4 sequentially arranged along the second direction D2 in the second column COL2 adjacent to the first column COL1 in the first direction D1 has been illustrated. For example, the first unit pixel UPX1 and the second unit pixel UPX2 may be adjacent to each other in the first direction D1, and the first unit pixel UPX1 and the third unit pixel UPX3 may be adjacent to each other in the second direction D2. The third unit pixel UPX3 and the fourth unit pixel UPX4 may be adjacent to each other in the first direction D1, and the second unit pixel UPX2 and the fourth unit pixel UPX4 may be adjacent to each other in the second direction D2.

The display area DA may include an emission area EA of each of the pixels PX and a non-emission area NEA positioned around the emission area EA. For example, the non-emission area NEA may be positioned between and/or around the emission areas EA, and may be around (e.g., surround) each emission area EA.

Each of the unit pixels UPX may include a plurality of pixels PX emitting light of different colors in each of the emission areas EA. As an example, each of the unit pixels UPX may include a first pixel PX1 including a first emission area EA1, a second pixel PX2 including a second emission area EA2, and a third pixel PX3 including a third emission area EA3.

In FIG. 4, positions of the pixels PX has been illustrated on the basis of the emission areas EA of the respective pixels PX, but the present disclosure is not limited thereto. For example, the pixel area where each pixel PX is provided may include an emission area EA where the light emitting element EL and/or the like is arranged and a pixel circuit area where circuit elements of the pixel circuit PXC are arranged. In one or more embodiments, the emission area EA and the pixel circuit area of each pixel PX may overlap each other.

An example in which one unit pixel UPX includes one first pixel PX1, one second pixel PX2, and one third pixel PX3 has been illustrated in FIG. 4, but the present disclosure is not limited thereto. For example, types (kinds), the number, ratios, and/or the like, of pixels PX included in each unit pixel UPX may be variously changed according to one or more embodiments.

The first emission area EA1, the second emission area EA2, and the third emission area EA3 may be emission areas that emit light of a first color, light of a second color, and light of a third color, respectively. In one or more embodiments, the light of the first color, the light of the second color, and the light of the third color may be red light, green light, and blue light, respectively. For example, the first emission area EA1 may be a red emission area emitting red light, the second emission area EA2 may be a green emission area emitting green light, and the third emission area EA3 may be a blue emission area emitting blue light. In this case, the first pixel PX1, the second pixel PX2, and the third pixel PX3 may be a red pixel, a green pixel, and a blue pixel, respectively. However, the present disclosure is not limited thereto. For example, a color (or a wavelength) of light emitted from each emission area EA, a type or kind of each pixel PX, and/or the like, may be changed according to one or more embodiments.

The first pixel PX1 may include a light emitting element EL (e.g., a red light emitting element) emitting the light of the first color or may include a light emitting element EL emitting light of a specific color (e.g., a blue color or a white color) and a wavelength shifter converting the light of the specific color into the light of the first color. Accordingly, the light of the first color may be emitted from the first emission area EA1.

The second pixel PX2 may include a light emitting element EL (e.g., a green light emitting element) emitting the light of the second color or may include a light emitting element EL emitting light of a specific color and a wavelength shifter converting the light of the specific color into the light of the second color. Accordingly, the light of the second color may be emitted from the second emission area EA2.

The third pixel PX3 may include alight emitting element EL (e.g., a blue light emitting element) emitting the light of the third color or may include a light emitting element EL emitting light of a specific color and a wavelength shifter converting the light of the specific color into the light of the third color. Accordingly, the light of the third color may be emitted from the third emission area EA3.

In one or more embodiments, the respective color filters CF transmitting light of colors to be emitted from the respective pixels PX therethrough may be arranged in the emission areas EA. For example, a first color filter (e.g., a red color filter) transmitting the light of the first color therethrough may be arranged in the first emission area EA1, and a second color filter (e.g., a green color filter) transmitting the light of the second color therethrough may be arranged in the second emission area EA2. A third color filter (e.g., a blue color filter) transmitting the light of the third color therethrough may be arranged in the third emission area EA3.

Each of the emission areas EA may have a rectangular shape, a non-rectangular polygonal shape, a circular shape, an elliptical shape, or other shapes. The emission areas EA may have substantially the same shape and size or have different shapes and/or sizes.

For example, depending on one or more suitable factors such as aperture ratios (e.g., areas or ratios of emission areas where light generated from the respective pixels PX is transmitted through color filters of the respective colors provided in a color filter layer and is then emitted to the outside), transmissivity, luminous efficiency, lifespans, visibility, white balance, or color coordinates of the first pixel PX1, the second pixel PX2, and the third pixel PX3, shapes, sizes, ratios, arrangement forms, and/or the like, of the first emission area EA1, the second emission area EA2, and the third emission area EA3 may be determined or changed. In one or more embodiments, the first emission area EA1 and the second emission area EA2 may have the same size or similar sizes, and the third emission area EA3 may have a smaller size than each of the first emission area EA1 and the second emission area EA2. In one or more embodiments, the third emission area EA3 may be arranged (positioned) between the first emission area EA1 and the second emission area EA2 in the first direction D1, but the present disclosure is not limited thereto.

Each pixel PX may include a light emitting element EL arranged in each emission area EA. For example, each pixel PX may include a pixel electrode AE arranged in each emission area EA and a light emitting layer (e.g., a light emitting layer OL of FIGS. 5 to 7) and a common electrode CE (e.g., a common electrode CE in FIGS. 2 and 5 to 7) that are sequentially arranged on the pixel electrode AE. The pixel electrode AE, the light emitting layer, and the common electrode CE arranged in each emission area EA may constitute each light emitting element EL.

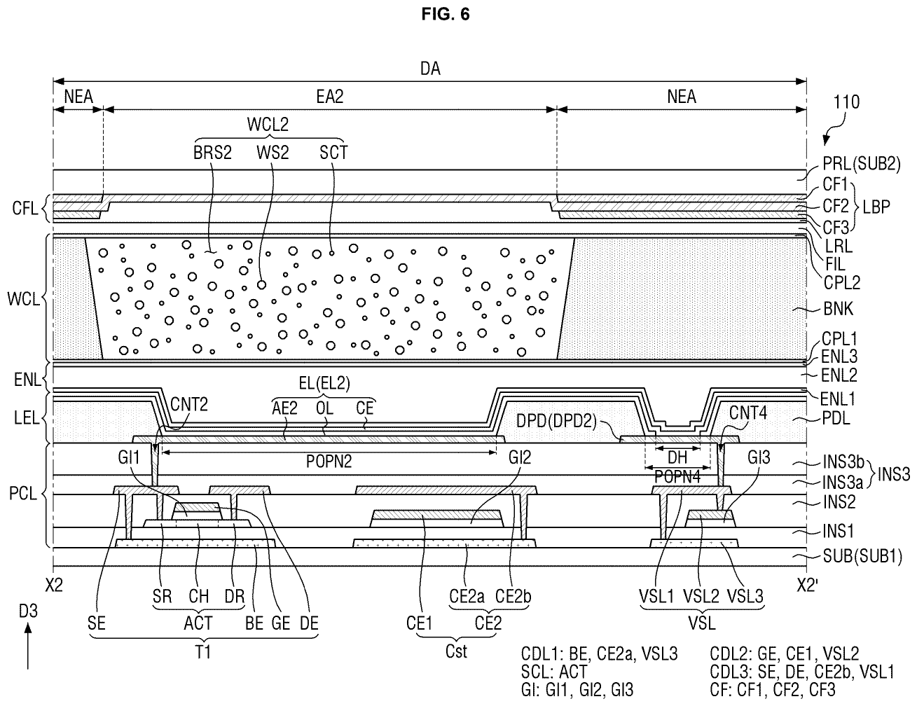

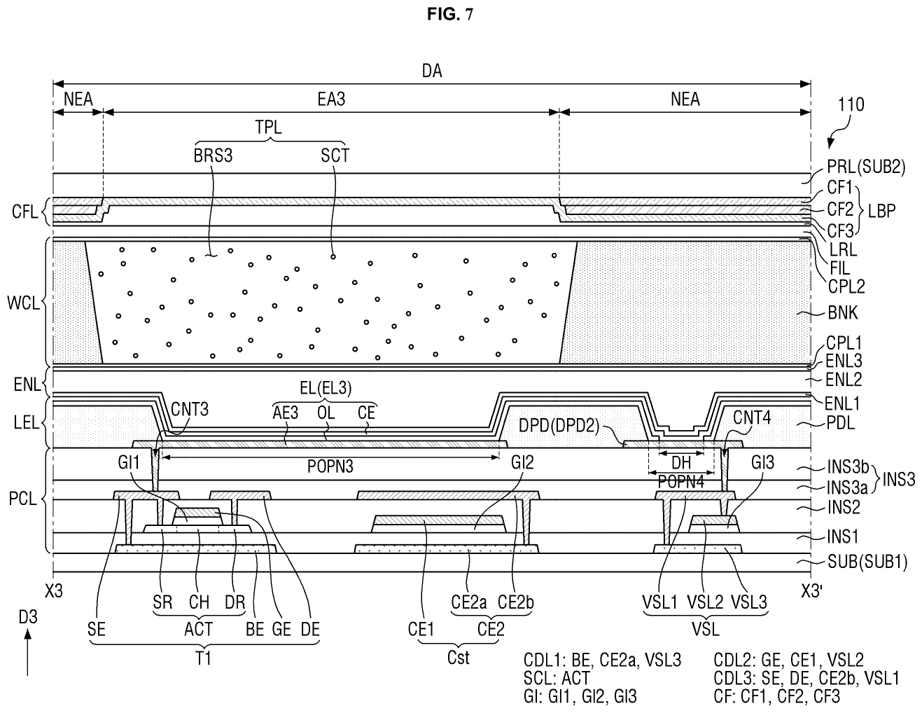

For example, the first pixel PX1 may include a light emitting element EL (e.g., a first light emitting element EL1 of FIG. 5) including a first pixel electrode AE1 arranged in the first emission area EA1 and a light emitting layer OL and a common electrode CE that are arranged on the first pixel electrode AE1. The second pixel PX2 may include a light emitting element EL (e.g., a second light emitting element EL2 of FIG. 6) including a second pixel electrode AE2 arranged in the second emission area EA2 and a light emitting layer OL and a common electrode CE that are arranged on the second pixel electrode AE2. The third pixel PX3 may include a light emitting element EL (e.g., a third light emitting element EL3 of FIG. 7) including a third pixel electrode AE3 arranged in the third emission area EA3 and a light emitting layer OL and a common electrode CE that are arranged on the third pixel electrode AE3.

Each pixel electrode AE may be mainly positioned in each emission area EA. Each pixel electrode AE may have a shape and/or a size corresponding to each emission area EA, but the present disclosure is not limited thereto. In one or more embodiments, a portion (e.g., at least a portion of an edge portion) of at least one pixel electrode AE may be positioned outside the emission area EA. In one or more embodiments, an edge portion of each pixel electrode AE may be covered with a pixel defining layer PDL.

In one or more embodiments, the common electrode CE may be entirely arranged in the display area DA. The common electrode CE may be electrically connected to pad electrodes DPD through drilling holes DH arranged on the pad electrodes DPD.

In one or more embodiments, the light emitting layer OL may be interposed between the pixel electrodes AE and the common electrode CE, and may be entirely arranged in the display area DA. Each drilling hole DH may penetrate through the light emitting layer on each pad electrode DPD.

The display device 100 may further include a pixel defining layer PDL arranged at least in the display area DA and covering edge portions of the pixel electrodes AE and the pad electrodes DPD. The pixel defining layer PDL may be opened to expose the pixel electrode AE in each emission area EA. For example, the pixel defining layer PDL may include openings corresponding to the emission areas EA of the pixels PX. The openings of the pixel defining layer PDL may have a shape and/or a size that are similar to or the same as a shape and/or a size of the emission areas EA, but the present disclosure is not limited thereto. In one or more embodiments, the pixel defining layer PDL may be arranged on edge portions of the emission areas EA and/or on the edge portions of the pixel electrodes AE in the non-emission area NEA. The pixel defining layer PDL may be opened to expose the pad electrode DPD in each drilling area (or connection area) where each pad electrode DPD is arranged. For example, the pixel defining layer PDL may include an opening exposing each pad electrode DPD in an area where the drilling hole DH is arranged.

Each pixel electrode AE may be electrically connected to the pixel circuit PXC (e.g., at least one circuit element constituting each pixel circuit PXC, including the first transistor T1 in FIG. 3) of each pixel PX through each connection hole CNT (e.g., each contact hole or via hole). In one or more embodiments, each connection hole CNT may be covered with the pixel defining layer PDL.

In one or more embodiments, each pixel electrode AE may be electrically connected to the pixel circuit PXC of each pixel PX at or around an edge portion positioned at one end of each unit pixel UPX. For example, a first pixel electrode AE1 of the first unit pixel UPX1 may be electrically connected to a circuit element constituting the pixel circuit PXC of the first pixel PX1 through a first connection hole CNT1 at (or near) a third edge portion EDG3 positioned at one end (e.g., a lower end) of the first unit pixel UPX1. A second pixel electrode AE2 of the first unit pixel UPX1 may be electrically connected to a circuit element constituting the pixel circuit PXC of the second pixel PX2 through a second connection hole CNT2 at (or near) the third edge portion EDG3 of the first unit pixel UPX1. A third pixel electrode AE3 of the first unit pixel UPX1 may be electrically connected to a circuit element constituting the pixel circuit PXC of the third pixel PX3 through a third connection hole CNT3 around (or inside) the third edge portion EDG3 of the first unit pixel UPX1. A first pixel electrode AE1, a second pixel electrode AE2, and a third pixel electrode AE3 of the second unit pixel UPX2 may be electrically connected to circuit elements constituting the pixel circuit PXC of the first pixel PX1, the pixel circuit PXC of the second pixel PX2, and the pixel circuit PXC of the third pixel PX3, respectively, through a first connection hole CNT1, a second connection hole CNT2, and a third contact hole CNT3, respectively, at (or near) a fourth edge portion EDG4 positioned at one end (e.g., a lower end) of the second unit pixel UPX2.

The display device 100 may further include pad electrodes DPD positioned only in some of the pixel columns COL of the display area DA. For example, the display device 100 may include a plurality of pad electrodes DPD positioned in some pixel columns COL (e.g., a first group of pixel columns) including the first column COL1. The pad electrodes DPD may not be arranged in the other pixel columns COL (e.g., a second group of pixel columns) including the second column COL2.

Each pad electrode DPD (also referred to as a “connection electrode” or a “drilling pad”) may be electrically connected to a second power line VSL (e.g., the second power line VSL of FIG. 2) to which a common voltage ELVSS is applied through each fourth connection hole CNT4. In one or more embodiments, each fourth connection hole CNT4 may be covered with the pixel defining layer PDL. The pixel defining layer PDL may include openings exposing a portion of each of the pad electrodes DPD, and may cover the other portion of each of the pad electrodes DPD. For example, the pixel defining layer PDL may expose a portion of each of the pad electrodes DPD including an area where each drilling hole DH is arranged, and cover the other portion (e.g., the edge portion) of each of the pad electrodes DPD. In one or more embodiments, each drilling hole DH may be a laser drilling hole formed by a laser drilling method using a laser, but the present disclosure is not limited thereto. Each pad electrode DPD may be electrically connected to the common electrode CE through each drilling hole DH. For example, each pad electrode DPD may be a connection electrode connected between the second power line VSL and the common electrode CE. In one or more embodiments, each pad electrode DPD may be a laser drilling pad connected to the common electrode CE through the laser drilling hole, but the present disclosure is not limited thereto.

In one or more embodiments, at least one pad electrode DPD may be arranged in each of the pixel columns COL including the pad electrodes DPD. For example, the first column COL1 may include a plurality of pad electrodes DPD including a first pad electrode DPD1, a second pad electrode DPD2, and a third pad electrode DPD3 positioned around the first unit pixel UPX1 and the third unit pixel UPX3. One or more embodiments in which the pad electrodes DPD are arranged at both (e.g., opposite) ends of each unit pixel UPX (e.g., a first edge portion EDG1 corresponding to an upper end of each unit pixel UPX in the second direction D2 and the third edge portion EDG3 corresponding to a lower end of each unit pixel UPX in the second direction D2) positioned in the pixel column COL (e.g., the first pixel column COL1) including the pad electrodes DPD has been illustrated in FIG. 4, but the present disclosure is not limited thereto. For example, the pad electrodes DPD may be arranged only on at least one end of unit pixels UPX positioned in some pixel rows, and may not be arranged around unit pixels UPX positioned in the other pixel rows. An arrangement cycle (pattern), an arrangement form, and/or the like, of the pad electrodes DPD may be variously changed according to one or more embodiments.

In one or more embodiments, a form of the unit pixels UPX arranged in the pixel columns COL that include the pad electrodes DPD may be different from a form of the unit pixels UPX arranged in the pixel columns COL that do not include the pad electrodes DPD. For example, an arrangement form of the first emission area EA1, the second emission area EA2, and the third emission area EA3 of each of the unit pixels UPX arranged in the first pixel column COL1 may be different from an arrangement form of the first emission area EA1, the second emission area EA2, and the third emission area EA3 of each of the unit pixels UPX arranged in the second pixel column COL2.

The first unit pixel UPX1 may include the first edge portion EDG1 and the third edge portion EDG3 positioned at both (e.g., opposite) ends thereof in the second direction D2. For example, the first edge portion EDG1 may be an upper edge portion of the first unit pixel UPX1, and the third edge portion EDG3 may be a lower edge portion of the first unit pixel UPX1.

In one or more embodiments, at the first edge portion EDG1 of the first unit pixel UPX1, only the first emission area EA1 and the second emission area EA2 selected from among the first emission area EA1, the second emission area EA2, and the third emission area EA3 of the first unit pixel UPX1 may be disposed (e.g., arranged or positioned). For example, at the first edge portion EDG1 of the first unit pixel UPX1, upper edge portions of the first emission area EA1 and the second emission area EA2 may be arranged adjacent to each other.

In one or more embodiments, the third emission area EA3 of the first unit pixel UPX1 may be arranged at a position spaced and/or apart (e.g., spaced apart or separated) from the first edge portion EDG1 in a unit pixel area where the first unit pixel UPX1 is arranged. For example, an upper edge portion of the third emission area EA3 of the first unit pixel UPX1 may be arranged between the first edge portion EDG1 and the third edge portion EDG3. In one or more embodiments, on the basis of a central portion between the first edge portion EDG1 and the third edge portion EDG3 of the first unit pixel UPX1, the third emission area EA3 may be positioned between the first emission area EA1 and the second emission area EA2 in the first direction D1. In one or more embodiments, the first emission area EA1 and the second emission area EA2 may be positioned on the right side and the left side of the third emission area EA3, respectively, but the present disclosure is not limited thereto. For example, the positions of the first emission area EA1 and the second emission area EA2 may be reversed.

The first pad electrode DPD1 may be further arranged at the first edge portion EDG1 of the first unit pixel UPX1. For example, a portion of the first pad electrode DPD1 may be arranged between the first pixel electrode AE1 and the second pixel electrode AE2 of the first unit pixel UPX1. In one or more embodiments, the first pad electrode DPD1 may be arranged to be spaced and/or apart (e.g., spaced apart or separated) from the pixel electrodes AE, at the same layer as the pixel electrodes AE.

In one or more embodiments, at the first edge portion EDG1 of the first unit pixel UPX1, the first pad electrode DPD1 may overlap the first emission area EA1 and the second emission area of the first unit pixel UPX1. For example, when viewed on the plane (e.g., in a plan view) defined by the first direction D1 and the second direction D2, the first emission area EA1 and the second emission area EA2 of the first unit pixel UPX1 may extend to the outside of the first pixel electrode AE1 and the second pixel electrode AE2 of the first unit pixel UPX1, respectively, around the first pad electrode DPD1 to overlap portions of the first pad electrode DPD1. That is, when viewed in the plan view defined by the first direction D1 and the second direction D2, the first emission area EA1 and the second emission area EA2 of the first unit pixel UPX1 may extend beyond the first pixel electrode AE1 and the second pixel electrode AE2, respectively, around the first pad electrode DPD1, overlapping portions of the first pad electrode DPD1.

In one or more embodiments, at the third edge portion EDG3 of the first unit pixel UPX1, the first emission area EA1, the second emission area EA2, and the third emission area EA3 of the first unit pixel UPX1 may all be arranged (e.g., positioned). For example, at the third edge portion EDG3 of the first unit pixel UPX1, lower edge portions of the first emission area EA1, the second emission area EA2, and the third emission area EA3 may be arranged.

In one or more embodiments, the second pad electrode DPD2 may be further arranged at the third edge portion EDG3 of the first unit pixel UPX1. For example, a portion of the second pad electrode DPD2 may be arranged between the first pixel electrode AE1 and the second pixel electrode AE2 of the first unit pixel UPX1 at the third edge portion EDG3 of the first unit pixel UPX1.

In one or more embodiments, the third pixel electrode AE3 of the first unit pixel UPX1 may be arranged inside of (e.g., above) the second pad electrode DPD2 in a first unit pixel area where the first unit pixel UPX1 is arranged. When viewed on the plane defined by the first direction D1 and the second direction D2 (e.g., a plan view), the third emission area EA3 of the first unit pixel UPX1 may extend outside of the third pixel electrode AE3 of the first unit pixel UPX1 to overlap a portion of the second pad electrode DPD. That is, when viewed in a plan view defined by the first direction D1 and the second direction D2, the third emission area EA3 of the first unit pixel UPX1 may extend beyond the third pixel electrode AE3, overlapping a portion of the second pad electrode DPD. At the third edge portion EDG3 of the first unit pixel UPX1, the second pad electrode DPD2 may be arranged between the first emission area EA1 and the second emission area EA2 of the first unit pixel UPX1 and may overlap the third emission area EA3 of the first unit pixel UPX1.

The second unit pixel UPX2 may include a second edge portion EDG2 and the fourth edge portion EDG4 positioned at both (e.g., opposite) ends thereof in the second direction D2. For example, the second edge portion EDG2 may be an upper edge portion of the second unit pixel UPX2, and the fourth edge portion EDG4 may be a lower edge portion of the second unit pixel UPX2. The second edge portion EDG2 of the second unit pixel UPX2 may be adjacent to the first edge portion EDG1 of the first unit pixel UPX1 in the first direction D1. The fourth edge portion EDG4 of the second unit pixel UPX2 may be adjacent to the third edge portion EDG3 of the first unit pixel UPX1 in the first direction D1.

In one or more embodiments, at the second edge portion EDG2 of the second unit pixel UPX2, the first emission area EA1, the second emission area EA2, and the third emission area EA3 of the second unit pixel UPX2 may all be arranged. For example, at the second edge portion EDG2 of the second unit pixel UPX2, upper edge portions of the first emission area EA1, the second emission area EA2, and the third emission area EA3 may be arranged.

In one or more embodiments, at the second edge portion EDG2 of the second unit pixel UPX2, the third emission area EA3 may be positioned between the first emission area EA1 and the second emission area EA2. As an example, the first emission area EA1 and the second emission area EA2 may be positioned on the right side and the left side of the third emission area EA3, respectively. The positions of the first emission area EA1 and the second emission area EA2 may be reversed.

In one or more embodiments, at the fourth edge portion EDG4 of the second unit pixel UPX2, only the first emission area EA1 and the second emission area EA2 of (e.g., selected from among) the first emission area EA1, the second emission area EA2, and the third emission area EA3 of the second unit pixel UPX2 may be arranged. For example, at the fourth edge portion EDG4 of the second unit pixel UPX2, lower edge portions of the first emission area EA1 and the second emission area EA2 may be arranged adjacent to each other.

In one or more embodiments, the third emission area EA3 of the second unit pixel UPX2 may be arranged at a position spaced and/or apart (e.g., spaced apart or separated) from the fourth edge portion EDG4 in a unit pixel area where the second unit pixel UPX2 is arranged. For example, a lower edge portion of the third emission area EA3 of the second unit pixel UPX2 may be arranged between the second edge portion EDG2 and the fourth edge portion EDG4.

In one or more embodiments, the first pixel electrode AE1, the second pixel electrode AE2, and the third pixel electrode AE3 of the second unit pixel UPX2 may be electrically connected to respective pixel circuits PXC through respective connection holes CNT positioned at the fourth edge portion EDG4 of the second unit pixel UPX2. For example, the third pixel electrode AE3 of the second unit pixel UPX2 may extend the outside of the third emission area EA3, and may be connected to a pixel circuit PXC provided in the third pixel PX3 of the second unit pixel UPX2 through a third connection hole CNT3 at the fourth edge portion EDG4.

Embodiments in which only the first emission area EA1 and the second emission area EA2 of the first unit pixel UPX1 are exposed at the first edge portion EDG1 of the first unit pixel UPX1 and the first emission area EA1, the second emission area EA2, and the third emission area EA3 of the first unit pixel UPX1 are all exposed at the third edge portion EDG3 of the first unit pixel UPX1 has been illustrated in FIG. 4, but the present disclosure is not limited thereto. For example, in one or more embodiments, the first emission area EA1, the second emission area EA2, and the third emission area EA3 of the first unit pixel UPX1 may all be exposed at the first edge portion EDG1 of the first unit pixel UPX1, and only the first emission area EA1 and the second emission area EA2 of the first unit pixel UPX1 may be exposed at the third edge portion EDG3 of the first unit pixel UPX1. As an example, the first unit pixel UPX1 may have the upside-down (or inverted) form in FIG. 4. In such embodiments, the form of the second unit pixel UPX2 may also be changed. For example, only the first emission area EA1 and the second emission area EA2 of the second unit pixel UPX2 may be exposed at the second edge portion EDG2 of the second unit pixel UPX2 and the first emission area EA1, the second emission area EA2, and the third emission area EA3 of the second unit pixel UPX2 may all be exposed at the fourth edge portion EDG4 of the second unit pixel UPX2. As an example, the second unit pixel UPX2 may have the upside-down (or inverted) form in FIG. 4.

In one or more embodiments, emission areas EA emitting light of a color having the best visibility among the emission areas EA of each unit pixel UPX may be positioned at both (e.g., opposite) edge portions positioned at both (e.g., opposite) ends of each unit pixel UPX. As an example, the second emission area EA2 emitting the green light among the emission areas EA of the first unit pixel UPX1 may be positioned at both the first edge portion EDG1 and the third edge portion EDG3 of the first unit pixel UPX1.

In one or more embodiments, the unit pixels UPX arranged in each pixel column COL may have substantially the same form and/or structure. For example, the first unit pixel UPX1 and the third unit pixel UPX3, arranged in the first column COL1, may have substantially the same form and/or structure, and the second unit pixel UPX2 and the fourth unit pixel UPX4, arranged in the second column COL2, may have substantially the same form and/or structure.

FIG. 5 is a cross-sectional view illustrating a portion of a display panel 110 according to one or more embodiments of the present disclosure. FIG. 6 is a cross-sectional view illustrating a portion of the display panel 110 according to one or more embodiments of the present disclosure. FIG. 7 is a cross-sectional view illustrating a portion of the display panel 110 according to one or more embodiments of the present disclosure.

For example, FIGS. 5, 6, and 7 illustrate embodiments of a cross section of the first pixel PX1 corresponding to line X1-X1′ of FIG. 4, a cross section of the second pixel PX2 corresponding to line X2-X2′ of FIG. 4, and a cross section of the third pixel PX3 corresponding to line X3-X3′ of FIG. 4, respectively. FIGS. 5 to 7 illustrate a portion of a light emitting display panel including light emitting elements EL (e.g., tandem organic light emitting diodes) as an example of a portion of the display panel 110.

Referring to FIGS. 5 to 7 in addition to FIGS. 1 to 4, the display panel 110 may include a substrate SUB (or a lower substrate SUB1), a panel circuit layer PCL, a light emitting element layer LEL, and an encapsulation layer ENL. In one or more embodiments, the display panel 110 may further include a light conversion layer WCL, a color filter layer CFL, and a protective layer PRL. The panel circuit layer PCL, the light emitting element layer LEL, the encapsulation layer ENL, the light conversion layer WCL, the color filter layer CFL, and the protective layer PRL may be arranged to overlap each other on the substrate SUB. As an example, the panel circuit layer PCL, the light emitting element layer LEL, the encapsulation layer ENL, the light conversion layer WCL, the color filter layer CFL, and the protective layer PRL may be sequentially arranged on the substrate SUB along the third direction D3. Positions, configurations, and/or the like, of the panel circuit layer PCL, the light emitting element layer LEL, the encapsulation layer ENL, the light conversion layer WCL, the color filter layer CFL, and/or the protective layer PRL may be changed according to one or more embodiments.

In one or more embodiments, the protective layer PRL may be an upper substrate SUB2, and at least one of the light conversion layer WCL and/or the color filter layer CFL may be formed on the upper substrate SUB2. As an example, the lower substrate SUB1 on which the panel circuit layer PCL, the light emitting element layer LEL, the encapsulation layer ENL, the light conversion layer WCL, and/or the like, are formed and the upper substrate SUB2 on which the color filter layer CFL is formed may be bonded to each other with a filler FIL interposed therebetween.

The substrate SUB is a base member for forming the display panel 110, and may be a rigid or flexible substrate (or film). In one or more embodiments, the substrate SUB may be a substrate including an insulating material such as glass and having rigid characteristics, and may not be bent. In one or more embodiments, the substrate SUB may be a flexible substrate including polyimide or other insulating materials and capable of being deformed, for example, bent, folded, or rolled, and may or may not be bent. A type or kind and/or a material of the substrate SUB may be changed according to one or more embodiments.

The panel circuit layer PCL (e.g., a pixel circuit layer or a thin film transistor layer) may be arranged on the substrate SUB. The panel circuit layer PCL may include circuit elements including transistors T and capacitors Cst of the pixels PX, and lines (e.g., signal lines and power lines). In one or more embodiments, the panel circuit layer PCL may further include circuit elements of the first driver 120 (e.g., driver transistors and/or driver capacitors provided in the first driver 120) and/or additional conductive patterns (e.g., bridge patterns).

FIGS. 5 to 7 illustrate the first transistor T1 and the capacitor Cst of each pixel PX as an example of the circuit elements that may be provided in the panel circuit layer PCL. FIGS. 5 to 7 illustrate a portion of the second power line VSL and the pad electrode DPD (e.g., the second pad electrode DPD2) connected to the second power line VSL as an example of lines that may be provided in the panel circuit layer PCL.

Embodiments in which the panel circuit layer PCL is arranged directly on the substrate SUB has been illustrated in FIGS. 5 to 7, but the present disclosure is not limited thereto. For example, the display panel 110 may further include a barrier layer arranged on the substrate SUB, and the panel circuit layer PCL may be arranged on the barrier layer.

The panel circuit layer PCL may include a plurality of conductive layers and at least one semiconductor layer SCL. In the conductive layers, electrodes constituting the circuit elements (e.g., the transistors T and the capacitor Cst constituting each pixel circuit PXC) of the panel circuit layer PCL, conductive patterns (e.g., bridge electrodes) connected to the circuit elements, lines, and/or the like, may be provided. In the semiconductor layer SCL, active layers ACT of the transistors T in the panel circuit layer PCL may be provided.

In one or more embodiments, the panel circuit layer PCL may include a first conductive layer CDL1 (e.g., a bottom conductive layer), the semiconductor layer SCL, a second conductive layer CDL2 (e.g., a gate conductive layer), and a third conductive layer CDL3 (e.g., a source-drain conductive layer or a data conductive layer) that are sequentially arranged on the substrate SUB along the third direction D3. In one or more embodiments, the panel circuit layer PCL may further include at least one conductive layer arranged on the third conductive layer CDL3 and at least one insulating layer covering the at least one conductive layer. The at least one conductive layer may include a bridge electrode connecting the light emitting element EL and the pixel circuit PXC (e.g., the first transistor T1) of each pixel PX to each other, to at least one line, and/or the like.

Patterns included in each conductive layer of the panel circuit layer PCL (e.g., electrodes, conductive patterns, and/or lines of each conductive layer) may each include a conductive material. For example, the patterns provided in each of the first conductive layer CDL1, the second conductive layer CDL2, and the third conductive layer CDL3 may each include at least one of copper (Cu), titanium (Ti), molybdenum (Mo), aluminum (Al), chromium (Cr), gold (Au), silver (Ag), platinum (Pt), palladium (Pd), nickel (Ni), neodymium (Nd), iridium (Ir), tantalum (Ta), tungsten (W), magnesium (Mg), and/or other metals, alloys thereof, and/or other conductive materials. In one or more embodiments, patterns included in the same (substantially the same) conductive layer may be formed concurrently (e.g., simultaneously) using the same conductive material.

In one or more embodiments, the respective patterns provided in each conductive layer of the panel circuit layer PCL may have a single-layer or multilayer structure. For example, the patterns provided in the first conductive layer CDL1, the second conductive layer CDL2, and the third conductive layer CDL3, respectively, may have a single-layer or multilayer structure. In one or more embodiments, the patterns included in the same (substantially the same) conductive layer may have the same cross-sectional structure.

The panel circuit layer PCL may further include a plurality of insulating layers and/or insulating patterns arranged on the substrate SUB. For example, the panel circuit layer PCL includes a first insulating layer INS1, a gate insulating layer GI, a second insulating layer INS2, and a third insulating layer INS3 that are sequentially arranged on the substrate SUB along the third direction D3.

In one or more embodiments, at least one insulating layer provided in the panel circuit layer PCL may be entirely arranged in (e.g., arranged across the entirety of) the display area DA. For example, the first insulating layer INS1, the second insulating layer INS2, and the third insulating layer INS3 may be entirely arranged in (e.g., arranged across the entirety of) the display area DA.

The first insulating layer INS1 may be arranged on the first conductive layer CDL1. For example, the first insulating layer INS1 may be arranged on the substrate SUB and cover the patterns of the first conductive layer CDL1. The first insulating layer INS1 may include at least one inorganic insulating layer including an inorganic insulating material (e.g., silicon nitride, silicon oxide, silicon oxynitride, titanium oxide, aluminum oxide, and/or other inorganic insulating materials).

The gate insulating layer GI may be arranged on the first insulating layer INS1 and the semiconductor layer SCL. The gate insulating layer GI may cover a portion of each of the first insulating layer INS1 and the semiconductor layer SCL. The gate insulating layer GI may include at least one inorganic insulating layer including an inorganic insulating material.

In one or more embodiments, the gate insulating layer GI may be partially arranged only (e.g., arranged to cover only a part of) in (e.g., arranged to cover only a part of) each pixel area and a portion of the display area DA including each pixel area. However, the present disclosure is not limited thereto. For example, the gate insulating layer GI may also be entirely arranged in (e.g., arranged across the entirety of) the display area DA so as to entirely cover the first insulating layer INS1 and the semiconductor layer SCL.

In one or more embodiments, the gate insulating layer GI may include a first gate insulating layer GI1 (also referred to as a “first gate insulating pattern”) that is arranged on a portion of each active layer ACT provided in the semiconductor layer SCL and a second gate insulating layer GI2 (also referred to as a “second gate insulating pattern”) and a third gate insulating layer GI3 (also referred to as a “third gate insulating pattern”) that are arranged on the first insulating layer INS1 and do not overlap the active layer ACT. For example, the first gate insulating layer GI1 may be arranged between a portion of the active layer ACT including a channel region CH and a gate electrode GE, and the second gate insulating layer GI2 may be arranged between the first insulating layer INS1 and a first capacitor electrode CE1. The first gate insulating layer GI1 and the second gate insulating layer GI2 may be an integrated insulating pattern connected to each other in plan view or be individual insulating patterns apart and/or separated from each other. The third gate insulating layer GI3 may be arranged between the first insulating layer INS1 and a second line layer VSL2 of the second power line VSL.

The second insulating layer INS2 may be arranged on the first insulating layer INS1, the semiconductor layer SCL, the gate insulating layer GI, and the second conductive layer CDL2. For example, the second insulating layer INS2 may be arranged on the first insulating layer INS1 and cover the semiconductor layer SCL, the gate insulating layer GI, and the patterns of the second conductive layer CDL2. The second insulating layer INS2 may include at least one inorganic insulating layer including an inorganic insulating material.

The third insulating layer INS3 may be arranged on the third conductive layer CDL3. For example, the third insulating layer INS3 may be arranged on the second insulating layer INS2 and cover the patterns of the third conductive layer CDL3.

The third insulating layer INS3 may include at least one organic insulating layer including an organic insulating material (e.g., an acrylic resin, an epoxy resin, a phenolic resin, a polyamide resin, a polyimide resin, and/or other organic insulating materials). A surface of the third insulating layer INS3 (e.g., an upper surface of a second layer INS3b) may be substantially flat. The third insulating layer INS3 may include an inorganic insulating layer or may not include an (e.g., may exclude any) inorganic insulating layer.

In one or more embodiments, the third insulating layer INS3 may be formed as multiple layers including a first layer INS3a and a second layer INS3b that are sequentially arranged on the second insulating layer INS2 and the third conductive layer CDL3. The first layer INS3a of the third insulating layer INS3 may be an inorganic insulating layer including an inorganic insulating material. The second layer INS3b of the third insulating layer INS3 may be an organic insulating layer including an organic insulating material.

The first transistor T1 may include an active layer ACT and a gate electrode GE (e.g., a top-gate electrode) arranged on a portion of the active layer ACT. In one or more embodiments, the first transistor T1 may further include at least one of a source electrode SE and/or a drain electrode DE. For example, the first transistor T1 may further include a source electrode SE connected to a source region SR of the active layer ACT and a drain electrode DE connected to a drain region DR of the active layer ACT. In one or more embodiments, the first transistor T1 may not include a (e.g., may exclude any) separate source electrode and/or drain electrode, and the source region SR and/or the drain region DR of the active layer ACT may be connected to other circuit elements, lines, conductive patterns, and/or the like, to function as a source electrode and/or a drain electrode of the first transistor T1.

In one or more embodiments, the first transistor T1 may further include a bottom electrode BE (or a light blocking layer) arranged below the active layer ACT. In one or more embodiments, the bottom electrode BE may be connected to one electrode (e.g., the source electrode SE or the gate electrode GE) of the first transistor T1, and may be utilized as a back-gate electrode BG adjusting characteristics of the first transistor T1. As an example, the bottom electrode BE may be connected to the source electrode SE of the first transistor T1 through at least one connection hole penetrating through the first insulating layer INS1 and the second insulating layer INS2. By disposing the bottom electrode BE below the active layer ACT, external light incident on the channel region CH and/or the like of the active layer ACT may be blocked, and operation characteristics of the first transistor T1 may be stabilized.

In one or more embodiments, the first transistor T1 may be an oxide transistor. As an example, the first transistor T1 may be an N-type or kind oxide transistor.

The bottom electrode BE may be provided in the first conductive layer CDL1 arranged on the substrate SUB. The first conductive layer CDL1 may be covered with the first insulating layer INS1.

The bottom electrode BE may overlap the active layer ACT and the gate electrode GE. For example, the bottom electrode BE may be arranged below the active layer ACT so as to overlap at least a portion of the active layer ACT including the channel region CH, and may face the gate electrode GE with the active layer ACT interposed therebetween.

The active layer ACT may be provided in the semiconductor layer SCL. The semiconductor layer SCL may be arranged on the first insulating layer INS1, and may be covered by the gate insulating layer GI and the second insulating layer INS2.

The active layer ACT may include the channel region CH and the source region SR and the drain region DR spaced and/or apart (e.g., spaced apart or separated) from each other with the channel region CH interposed therebetween. For example, the source region SR and the drain region DR may be positioned on both sides (e.g., opposite sides) of the channel region CH, respectively. The source region SR and the drain region DR may be regions made to be conductive so as to have a higher carrier concentration (e.g., electron concentration) than the channel region CH.

The active layer ACT may overlap the bottom electrode BE and the gate electrode GE. For example, a portion of the active layer ACT including the channel region CH may overlap the bottom electrode BE and the gate electrode GE in the third direction D3.

In one or more embodiments, the active layer ACT may include an oxide semiconductor. For example, the active layer ACT may include an oxide semiconductor including at least one of indium (In), gallium (Ga), zinc (Zn), tin (Sn), and/or hafnium (Hf), and/or one or more other oxide semiconductors. As an example, the active layer ACT may include at least one of zinc oxide (ZnO), zinc tin oxide (ZTO), indium zinc oxide (IZO), indium oxide (InO or In₂O₃), titanium oxide (TiO or TiO₂), indium gallium oxide (IGO), indium gallium zinc oxide (IGZO), indium gallium tin oxide (IGTO), indium zinc tin oxide (IZTO), indium tin gallium zinc oxide (ITGZO), and/or other oxide semiconductors.

The first gate insulating layer Gil may be arranged on the active layer ACT. For example, the first gate insulating layer Gil may be arranged between the active layer ACT and the gate electrode GE.

In one or more embodiments, the first gate insulating layer Gil may cover a portion of the active layer ACT including a portion overlapping the gate electrode GE and expose the other portion of the active layer ACT. As an example, the first gate insulating layer Gil may be arranged on a portion of the active layer ACT including the channel region CH, and may expose the source region SR and the drain region DR of the active layer ACT.

As the first gate insulating layer Gil exposes the source region SR and the drain region DR, the source region SR and the drain region DR may be appropriately, suitably, and/or easily made to be conductive in a manufacturing process of the display panel 110. For example, in a process of etching the gate insulating layer GI so as to expose at least a portion of each of the source region SR and drain region DR, oxygen vacancies may occur in the source region SR and the drain region DR. Accordingly, the source region SR and the drain region DR may be appropriately or suitably made to be conductive in a subsequent process (e.g., a process of forming the second insulating layer INS2) without performing a separate doping process.

The gate electrode GE may be arranged on the first gate insulating layer Gil. The gate electrode GE may be provided in the second conductive layer CDL2. The second conductive layer CDL2 may be arranged on the first insulating layer INS1 and the gate insulating layer GI, and may be covered by the second insulating layer INS2.

The gate electrode GE may be arranged on the active layer ACT. For example, the gate electrode GE may be arranged on the first gate insulating layer Gil covering the channel region CH of the active layer ACT. The gate electrode GE and the active layer ACT may be separated from each other with the first gate insulating layer Gil interposed therebetween.

The second insulating layer INS2 may be arranged on the gate electrode GE. The second insulating layer INS2 may cover the first insulating layer INS1, the active layer ACT, the gate insulating layer GI, and the second conductive layer CDL2.

The source electrode SE and the drain electrode DE may be arranged on the second insulating layer INS2. The source electrode SE and drain electrode DE may be provided in the third conductive layer CDL3. The third conductive layer CDL3 may be arranged between the second insulating layer INS2 and the third insulating layer INS3.

The source electrode SE may be connected to a portion of the active layer ACT. For example, the source electrode SE may be electrically connected to the source region SR of the active layer ACT through at least one connection hole penetrating through the second insulating layer INS2. In one or more embodiments, the source electrode SE may also be electrically connected to the bottom electrode BE.

The drain electrode DE may be connected to another portion of the active layer ACT. For example, the drain electrode DE may be connected to the drain region DR of the active layer ACT through at least one connection hole penetrating through the second insulating layer INS2.

The first transistor T1 of each pixel PX may be electrically connected to the light emitting element EL of each pixel PX. For example, the first transistor T1 arranged in each pixel area may be electrically connected to a pixel electrode AE of the light emitting element EL arranged in each pixel area in the light emitting element layer LEL.

The capacitor Cst may include capacitor electrodes forming capacitance. As an example, the capacitor Cst may include a first capacitor electrode CE1 and a second capacitor electrode CE2.

In one or more embodiments, the capacitor Cst may include a multilayer electrode. For example, at least one of the first capacitor electrode CE1 and/or the second capacitor electrode CE2 may have a multilayer structure including a plurality of sub-electrodes.

In one or more embodiments, the first capacitor electrode CE1 may be a single-layer electrode provided in the second conductive layer CDL2. However, the present disclosure is not limited thereto. For example, the first capacitor electrode CE1 may further include at least one sub-electrode provided in another conductive layer.

In one or more embodiments, the first capacitor electrode CE1 may be connected to the gate electrode GE of the first transistor T1 positioned in each pixel area. As an example, the first capacitor electrode CE1 may be provided in the second conductive layer CDL2 integrally with the gate electrode GE of the first transistor T1. For example, the first capacitor electrode CE1 and the gate electrode GE of the first transistor T1 may be formed as an integrated electrode connected to each other when viewed on the plane (e.g., in a plan view) defined by the first direction D1 and the second direction D2 (e.g., in a plan view). In such embodiments, the first gate insulating layer GI1 positioned beneath the gate electrode GE of the first transistor T1 and the second gate insulating layer GI2 positioned beneath the first capacitor electrode CE1 may be connected to each other.

In one or more embodiments, the second capacitor electrode CE2 may include a first sub-electrode CE2a provided in the first conductive layer CDL1 and a second sub-electrode CE2b provided in the third conductive layer CDL3. The first sub-electrode CE2a and the second sub-electrode CE2b of the second capacitor electrode CE2 may overlap the first capacitor electrode CE1. The first sub-electrode CE2a and the second sub-electrode CE2b of the second capacitor electrode CE2 may be electrically connected to each other through at least one connection hole penetrating through the first insulating layer INS1 and the second insulating layer INS2. The second capacitor electrode CE2 is formed in a multilayer structure, and accordingly, capacitance of the capacitor Cst may be appropriately or suitably secured by efficiently utilizing the pixel area having a limited size.

In one or more embodiments, the second capacitor electrode CE2 may be formed as a single electrode provided in the first conductive layer CDL1 or the third conductive layer CDL3. In one or more embodiments, the second capacitor electrode CE2 may be formed as a triple-layer or more electrode further including at least one sub-electrode provided in another conductive layer (e.g., a fourth conductive layer additionally formed between the third insulating layer INS3 and the light emitting element layer LEL).

In one or more embodiments, the second capacitor electrode CE2 may be connected to the source electrode SE of the first transistor T1 positioned in each pixel area. As an example, the first sub-electrode CE2a of the second capacitor electrode CE2 may be provided in the first conductive layer CDL1 integrally with the bottom electrode BE of the first transistor T1, and may be connected to the source electrode SE of the first transistor T1 through at least one connection hole. The second sub-electrode CE2b of the second capacitor electrode CE2 may be formed integrally with or separately from the source electrode SE of the first transistor T1 positioned in each pixel area.

The second power line VSL may be a single-layer or multilayer line provided in at least one conductive layer. As an example, the second power line VSL may include a first line layer VSL1 (also referred to as a “first sub-line”) provided in the third conductive layer CDL3.

In one or more embodiments, the second power line VSL may be a multilayer line provided in a plurality of conductive layers. For example, the second power line VSL may further include at least one of a second line layer VSL2 (also referred to as a “second sub-line”) provided in the second conductive layer CDL2 and/or a third line layer VSL3 (also referred to as a “third sub-line”) provided in the first conductive layer CDL1. The second line layer VSL2 may overlap the first line layer VSL1, and may be electrically connected to the first line layer VSL1 through at least one connection hole penetrating through the second insulating layer INS2. The third gate insulating layer GI3 may be arranged beneath the second line layer VSL2 (e.g., between the first insulating layer INS1 and the second line layer VSL2). The third line layer VSL3 may overlap the first line layer VSL1, and may be electrically connected to the first line layer VSL1 through at least one connection hole penetrating through the first insulating layer INS1 and the second insulating layer VSL2. In one or more embodiments, the third line layer VSL3 may not be directly connected to the first line layer VSL1, and may be electrically connected to the first line layer VSL1 through the second line layer VSL2.

The light emitting element layer LEL may be arranged on the panel circuit layer PCL. For example, the light emitting element layer LEL may be arranged on the third insulating layer INS3, and may be positioned at least in the display area DA.

The light emitting element layer LEL may include a light emitting element EL of each of the pixels PX. For example, the light emitting element layer LEL may include light emitting elements EL arranged in the emission areas EA of the pixels PX and a pixel defining layer PDL arranged around the light emitting elements EL. When viewed on the plane defined by the first direction D1 and the second direction D2 (e.g., in a plan view), the pixel defining layer PDL may be around (e.g., surround) the light emitting element EL of each pixel PX.

Each light emitting element EL may include a pixel electrode AE positioned in each emission area EA and a light emitting layer OL and a common electrode CE that are sequentially arranged on the pixel electrode AE. One of the pixel electrode AE and/or the common electrode CE of the light emitting element EL may be an anode electrode, and the other of the pixel electrode AE and/or the common electrode CE of the light emitting element EL may be a cathode electrode. As an example, the pixel electrode AE may be an anode electrode, and the common electrode CE may be a cathode electrode.

In one or more embodiments, the pixel electrode AE may be formed individually for each emission area EA. For example, the first pixel electrode AE1 may be arranged in the first emission area EA1 of the first pixel PX1. The second pixel electrode AE2 may be arranged in the second emission area EA2 of the second pixel PX2. The third pixel electrode AE3 may be arranged in the third emission area EA3 of the third pixel PX3. The first pixel electrode AE1, the second pixel electrode AE2, and the third pixel electrode AE3 may be apart and/or separated from each other.

Each pixel electrode AE may be connected to at least one transistor T (e.g., the first transistor T1) included in the corresponding pixel PX. For example, the first pixel electrode AE1 may be electrically connected to the first transistor T1 of the first pixel PX1 through a first connection hole CNT1 (or a first via hole) penetrating through the third insulating layer INS3 (see, e.g., FIG. 5). The second pixel electrode AE2 may be electrically connected to the first transistor T1 of the second pixel PX2 through a second connection hole CNT2 (or a second via hole) penetrating through the third insulating layer INS3 (see, e.g., FIG. 56). The third pixel electrode AE3 may be electrically connected to the first transistor T1 of the third pixel PX3 through a third connection hole CNT3 (or a third via hole) penetrating through the third insulating layer INS3 (see, e.g., FIG. 7).

In one or more embodiments, the display panel 110 may be a top emission-type or kind display panel, and the pixel electrode AE may include a metal layer including a metal such as Ag, Mg, Al, Pt, Pd, Au, Ni, Nd, Ir, and/or Cr. In one or more embodiments, the pixel electrode AE may further include a metal oxide layer overlapping the metal layer. As an example, the pixel electrode AE may have a double-layer structure such as indium tin oxide (ITO)/Ag, Ag/ITO, ITO/Mg, or ITO/MgF or a triple-layer structure such as ITO/Ag/ITO.

In one or more embodiments, the display panel 110 may further include pad electrodes DPD arranged at the same (substantially the same) layer as the pixel electrodes AE. For example, the pad electrodes DPD may be arranged on the panel circuit layer PCL. In one or more embodiments, the pixel electrodes AE and the pad electrodes DPD may be arranged to be spaced and/or apart (e.g., spaced apart or separated) from each other, and may be formed concurrently (e.g., simultaneously) with each other. For example, the pixel electrodes AE and the pad electrodes DPD may be formed concurrently (e.g., simultaneously) at the same (substantially the same) layer of the light emitting element layer LEL using the same conductive material. As an example, the pixel electrodes AE and the pad electrodes DPD may be formed to be apart and/or separated from each other by forming a single-layer or multilayer conductive film on the third insulating layer INS3 and etching the conductive film through an etching process using a mask.

Each pad electrode DPD may overlap a portion of the second power line VSL, and may be electrically connected to the second power line VSL through a fourth connection hole CNT4 (or a fourth via hole) penetrating through the third insulating layer INS3.

The pixel defining layer PDL may be arranged on the pixel electrodes AE and the pad electrodes DPD. For example, the pixel defining layer PDL may be arranged on portions of the pixel electrodes AE and the pad electrodes DPD. As an example, the pixel defining layer PDL may cover an edge portion of each pixel electrode AE, and may include an opening exposing the other portion of each pixel electrode AE. For example, the pixel defining layer PDL may include a first opening POPN1 exposing a portion of the first pixel electrode AE1, a second opening POPN2 exposing a portion of the second pixel electrode AE2, and a third opening POPN3 exposing a portion of the third pixel electrode AE3. In one or more embodiments, the pixel defining layer PDL may cover an edge portion of each pad electrode DPD, and may include a fourth opening POPN4 exposing the other portion (e.g., the portion other than the edge portion) of each pad electrode DPD.

The pixel defining layer PDL may be mainly arranged in the non-emission area NEA, and may have openings (e.g., the first opening POPN1, the second opening POPN2, and the third opening POPN3) corresponding to the emission areas EA. In one or more embodiments, the pixel defining layer PDL may also be arranged at an edge portion of each emission area EA. For example, the first opening POPN1 of the pixel defining layer PDL may have a smaller size than the first emission area EA1 and may be positioned inside the first emission area EA1. Similarly, the second opening POPN2 of the pixel defining layer PDL may have a smaller size than the second emission area EA2 and may be positioned inside the second emission area EA2. The third opening POPN3 of the pixel defining layer PDL may have a smaller size than the third emission area EA3 and may be positioned inside the third emission area EA3.

However, the present disclosure is not limited thereto. For example, the pixel defining layer PDL may also include an opening having a size greater than or equal to a size of the emission area EA, at a position corresponding to at least one emission area EA.

The pixel defining layer PDL may have the fourth opening POPN4 corresponding to each drilling area. In one or more embodiments, the pixel defining layer PDL may be opened wider than a drilling hole DH positioned in each drilling area. For example, the fourth opening POPN4 of the pixel defining layer PDL may overlap the drilling hole DH, and the drilling hole DH may be positioned inside (e.g., at the center of) the fourth opening POPN4 of the pixel defining layer PDL.

However, the present disclosure is not limited thereto. For example, the fourth opening POPN4 of the pixel defining layer PDL may also be integrated with the drilling hole DH. As an example, it is also possible to form the drilling hole DH so as to penetrate through the pixel defining layer PDL and the light emitting layer OL in a process of forming the drilling hole DH, instead of opening the pixel defining layer PDL of the drilling area before forming the drilling hole DH.

The pixel defining layer PDL may overlap a bank BNK of the light conversion layer WCL and a light blocking pattern LBP of the color filter layer CFL in the third direction D3. As an example, the pixel defining layer PDL may overlap the bank BNK and the light blocking pattern LBP in the non-emission area NEA.

In one or more embodiments, the pixel defining layer PDL may include at least one organic insulating layer including an organic insulating material. As an example, the pixel defining layer PDL may include an organic insulating material such as a polyacrylate resin, an epoxy resin, a phenolic resin, a polyamide resin, a polyimide resin, an unsaturated polyester resin, a polyphenylene ether resin, a polyphenylene sulfide resin, and/or benzocyclobutene (BCB), but the present disclosure is not limited thereto.

The light emitting layer OL may be arranged on each pixel electrode AE. In one or more embodiments, the light emitting layer OL may have a shape of a substantially continuous film formed across a plurality of emission areas EA and the non-emission area NEA. In one or more embodiments, the light emitting layer OL may be locally removed at (on) each pad electrode DPD by the drilling hole DH. As an example, each drilling hole DH may be formed by removing the light emitting layer OL at (on) each pad electrode DPD using a laser.

However, the present disclosure is not limited thereto. For example, the light emitting layer OL may also be formed individually in each emission area EA. As an example, the light emitting layers OL of the light emitting elements EL positioned in the respective emission areas EA may be formed to be apart and/or separated from each other.

In one or more embodiments, the light emitting layer OL may be to emit light of a third color, for example, blue light. However, the present disclosure is not limited thereto. For example, the light emitting layer OL may also emit white light and/or the like.

The light emitting layer OL may be positioned only within the display area DA, but the present disclosure is not limited thereto. For example, a portion of the light emitting layer OL may also be arranged in at least a portion of the non-display area NDA.

The light emitting layer OL of the light emitting element EL may include a high molecular material or a low molecular material. Light emitted from the light emitting layer OL may contribute to image display. The light emitting layer OL will be described in more detail later.

The common electrode CE may be arranged on the light emitting layer OL. In one or more embodiments, the common electrode CE may be a common electrode shared by the plurality of pixels PX. As an example, the common electrode CE may be entirely formed in (e.g., formed across the entirety of) the display area DA (or a portion of the display area DA) including the plurality of emission areas EA.

In one or more embodiments, the common electrode CE may overlap each pad electrode DPD, and may be electrically connected to each pad electrode DPD through the drilling hole DH (e.g., the drilling hole DH penetrating through the light emitting layer OL and/or the like) formed on each pad electrode DPD. For example, the common electrode CE may be in contact with the pad electrode DPD exposed by the drilling hole DH. The common electrode CE may be electrically connected to the second power line VSL of the panel circuit layer PCL through the pad electrode DPD. Accordingly, the common voltage ELVSS applied to the second power line VSL may be applied to the common electrode CE.

In one or more embodiments, the display panel 110 may be a top emission-type or kind display panel, and the common electrode CE may have semi-transmissive properties or transmissive properties. In one or more embodiments, the common electrode CE may include Ag, Mg, Cu, Al, Pt, Pd, Au, Ni, Nd, Ir, Cr, Li, Ca, LiF/Ca, LiF/Al, Mo, Ti and/or compounds or mixtures thereof such as a mixture of Ag and Mg, and may have semi-transmissive properties. In one or more embodiments, the common electrode CE may include tungsten oxide (WₓOₓ), titanium oxide (TiO₂), indium tin oxide (ITO), indium zinc oxide (IZO), zinc oxide (ZnO), indium tin zinc oxide (ITZO), magnesium oxide (MgO), and/or the like, and may have transmissive properties.

The pixel electrode AE, the light emitting layer OL, and the common electrode CE arranged in each emission area EA may constitute each light emitting element EL. For example, the first pixel electrode AE1, the light emitting layer OL, and the common electrode CE arranged in the first emission area EA1 may constitute a light emitting element EL (e.g., a first light emitting element EL1) of the first pixel PX1 (see, e.g., FIG. 5). The second pixel electrode AE2, the light emitting layer OL, and the common electrode CE arranged in the second emission area EA2 may constitute a light emitting element EL (e.g., a second light emitting element EL2) of the second pixel PX2 (see, e.g., FIG. 6). The third pixel electrode AE3, the light emitting layer OL, and the common electrode CE arranged in the third emission area EA3 may constitute a light emitting element EL (e.g., a third light emitting element EL3) of the third pixel PX3 (see, e.g., FIG. 7).

In one or more embodiments, the light emitting elements EL of the pixels PX may be to emit light of the same color. As an example, the first light emitting element EL1, the second light emitting element EL2, and the third light emitting element EL3 may be blue organic light emitting diodes that emit blue light.

In one or more embodiments, the light emitting element layer LEL may further include a capping layer covering the common electrode CE. For example, the light emitting element layer LEL may further include a capping layer arranged on the common electrode CE and including at least one of an inorganic material or an organic material, having light transmitting properties (i.e., including at least one inorganic or organic material with light-transmitting properties). The capping layer may improve viewing angle characteristics of the display panel 110 and may improve external luminous efficiency.

The encapsulation layer ENL may be arranged on the light emitting element layer LEL. The encapsulation layer ENL may cover the light emitting element layer LEL in the display area DA and extend to the non-display area NDA to be in contact with the panel circuit layer PCL. The encapsulation layer ENL may block or reduce permeation of oxygen or moisture into the light emitting element layer LEL and alleviate or reduce the likelihood of an electrical or physical shock to the panel circuit layer PCL and the light emitting element layer LEL. In one or more embodiments, the encapsulation layer ENL may include a first encapsulation layer ENL1, a second encapsulation layer ENL2, and a third encapsulation layer ENL3 that are sequentially arranged on the light emitting element layer LEL.

Each of the first encapsulation layer ENL1 and the third encapsulation layer ENL3 may be an inorganic encapsulation layer including an inorganic material. As an example, each of the first encapsulation layer ENL1 and the third encapsulation layer ENL3 may include silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, lithium fluoride, and/or the like.

The second encapsulation layer ENL2 may be an organic encapsulation layer including an organic material. As an example, the second encapsulation organic film ENL2 may include an acrylic resin, a methacrylic resin, polyisoprene, a vinyl-based resin, an epoxy-based resin, a urethane-based resin, a cellulose-based resin, a perylene-based resin, and/or the like.

The light conversion layer WCL may be arranged on the encapsulation layer ENL. In one or more embodiments, the light conversion layer WCL may be formed on the encapsulation layer ENL, but the present disclosure is not limited thereto. For example, the light conversion layer WCL may also be formed on the protective layer PRL (e.g., the upper substrate SUB2) and then arranged on the encapsulation layer ENL.

The light conversion layer WCL may include light transmitting members arranged in the emission areas EA and the bank BNK arranged in the non-emission area NEA. The light transmitting members may include a first light transmitting member WCL1 (also referred to as a “first light conversion layer”) arranged in the first emission area EA1, a second light transmitting member WCL2 (also referred to as a “second light conversion layer”) arranged in the second emission area EA2, and a third light transmitting member TPL (also referred to as a “light transmitting layer”) arranged in the third emission area EA3.

In one or more embodiments, the light conversion layer WCL may further include at least one capping layer. As an example, the light conversion layer WCL may further include a first capping layer CPL1 covering lower surfaces of the light transmitting members and the bank BNK and a second capping layer CPL2 covering upper surfaces of the light transmitting members and the bank BNK.

The first capping layer CPL1 may be arranged on the encapsulation layer ENL. The first capping layer CPL1 may be made of an inorganic material such as silicon nitride, silicon oxynitride, silicon oxide, titanium oxide, and/or aluminum oxide.

The first light transmitting member WCL1, the second light transmitting member WCL2, the third light transmitting member TPL, and the bank BNK may be arranged on the first capping layer CPL1.

The first light transmitting member WCL1 may convert some of the light of a third color (e.g., blue light) incident from the first light emitting element EL1 arranged in the first emission area EA1 into light of a first color (e.g., red light). The light of the first color converted by the first light transmitting member WCL1 may be transmitted through a first color filter CF1 and/or the like and then emitted to an upper portion of the display panel 110.

The first light transmitting member WCL1 may include a first base resin BRS1 and first wavelength shifters WS1. The first base resin BRS1 may include a light transmitting organic material. For example, the first base resin BRS1 may include an epoxy-based resin, an acrylic resin, a cardo-based resin, an imide-based resin, and/or the like. The first wavelength shifter WS1 may convert the light of the third color incident from the first light emitting element EL1 into the light of the first color. The first wavelength shifter WS1 may be a quantum dot (e.g., a red quantum dot), a quantum rod, a fluorescent material, or a phosphorescent material. In one or more embodiments, the first light transmitting member WCL1 may further include light diffusing (e.g., scattering) agents SCT such as titanium dioxide (TiO₂).

The second light transmitting member WCL2 may convert some of the light of a third color (e.g., blue light) incident from the second light emitting element EL2 arranged in the second emission area EA2 into light of a second color (e.g., green light). The light of the second color converted by the second light transmitting member WCL2 may be transmitted through a second color filter CF2 and/or the like and then emitted to an upper portion of the display panel 110.

The second light transmitting member WCL2 may include a second base resin BRS2 and second wavelength shifters WS2. The second base resin BRS2 may include a light transmitting organic material. For example, the second base resin BRS2 may include an epoxy-based resin, an acrylic resin, a cardo-based resin, an imide-based resin, and/or the like. The second wavelength shifter WS2 may convert the light of the third color incident from the second light emitting element EL2 into the light of the second color. The second wavelength shifter WS2 may be a quantum dot (e.g., a green quantum dot), a quantum rod, a fluorescent material, or a phosphorescent material. In one or more embodiments, the second light transmitting member WCL2 may further include light diffusing (e.g., scattering) agents SCT such as titanium dioxide (TiO₂).

The third light transmitting member TPL may diffuse and/or transmit light of a third color (e.g., blue light) incident from the third light emitting element EL3 arranged in the third emission area EA3. The light of the third color transmitted through the third light transmitting member TPL may be transmitted through a third color filter CF3 and/or the like and then emitted to an upper portion of the display panel 110.

The third light transmitting member TPL may include a third base resin BRS3. The third base resin BRS3 may include a light transmitting organic material. For example, the third base resin BRS3 may include an epoxy-based resin, an acrylic resin, a cardo-based resin, an imide-based resin, and/or the like. In one or more embodiments, the third light transmitting member TPL may further include light diffusing (e.g., scattering) agents SCT such as titanium dioxide (TiO₂).

The bank BNK may be arranged in the non-emission area NEA to partition or define the emission areas EA where the light transmitting members are provided. For example, the bank BNK may include openings corresponding to the emission areas EA of the pixels PX and be around (e.g., surround) the emission areas EA.

In one or more embodiments, the bank BNK may be formed to have a relatively great thickness in order to provide spaces where the light transmitting members are formed. As an example, a thickness of the bank BNK may be 1 μm to 10 μm, but the present disclosure is not limited thereto.

In one or more embodiments, the bank BNK may include an organic insulating material (e.g., an acrylic resin, an epoxy resin, a phenolic resin, a polyamide resin, a polyimide resin, and/or other organic insulating materials). In one or more embodiments, the bank BNK may further include a light blocking material. As an example, the bank BNK may include a dye and/or a pigment (e.g., an inorganic black pigment such as carbon black or an organic black pigment) having light blocking properties. Accordingly, the bank BNK may have light blocking properties.

The second capping layer CPL2 may be arranged on the first light transmitting member WCL1, the second light transmitting member WCL2, the third light transmitting member TPL, and the bank BNK. The second capping layer CPL2 may protect the light transmitting members and the bank BNK of the light conversion layer WCL from moisture, foreign substances, and/or the like. In one or more embodiments, the second capping layer CPL2 may include an inorganic material. In one or more embodiments, the second capping layer CPL2 may include the same material as the first capping layer CPL1, but the present disclosure is not limited thereto.

The color filter layer CFL may be arranged on the second capping layer CPL2. In one or more embodiments, the light conversion layer WCL and the color filter layer CFL may be formed on different substrate members (e.g., the lower substrate SUB1 and the upper substrate SUB2), respectively, and then coupled to each other so as to face each other, and the filler FIL may be arranged between the light conversion layer WCL and the color filter layer CFL.

The filler FIL may fill a space between the light conversion layer WCL and the color filter layer CFL. The filler FIL may be made of a material whose extinction coefficient is substantially 0. A refractive index and the extinction coefficient are correlated to each other, and as the refractive index decreases, the extinction coefficient may also decrease. In one or more embodiments, if (e.g., when) the refractive index is 1.7 or less, the extinction coefficient may substantially converge to 0. In one or more embodiments, the filler FIL may be made of a material having a refractive index of 1.7 or less, and accordingly, may prevent, minimize, or reduce a phenomenon in which the light emitted from the emitting element EL is absorbed while being transmitted through the filler FIL. In one or more embodiments, the filler FIL may be made of an organic material having a refractive index of 1.4 to 1.6.

The color filter layer CFL may include the color filters CF arranged in the respective emission areas EA. For example, the color filter layer CFL may include the first color filter CF1 arranged in the first emission area EA1, the second color filter CF2 arranged in the second emission area EA2, and the third color filter CF3 arranged in the emission area EA3. The color filter layer CFL may further include the light blocking pattern LBP arranged in the non-emission area NEA.

The first color filter CF1 may be to transmit the light of the first color therethrough and absorb, block, or reduce the light of the third color. For example, the first color filter CF1 may be to transmit the light of the first color converted from the light of the third color emitted from the first light emitting element EL1 by the first light transmitting member WCL1, and absorb, block, or reduce the light of the third color emitted from the first light emitting element EL1 that is not converted by the first light transmitting member WCL1. Accordingly, the light of the first color may be emitted from the first emission area EA1. As an example, the first color filter CF1 may be a red color filter, and the red light may be emitted from the first emission area EA1.

The second color filter CF2 may be to transmit the light of the second color therethrough and absorb, block, or reduce the light of the third color. For example, the second color filter CF2 may be to transmit the light of the second color converted from the light of the third color emitted from the second light emitting element EL2 by the second light transmitting member WCL2, and absorb, block, or reduce the light of the third color emitted from the second light emitting element EL2 that is not converted by the second light transmitting member WCL2. Accordingly, the light of the second color may be emitted from the second emission area EA2. As an example, the second color filter CF2 may be a green color filter, and the green light may be emitted from the second emission area EA2.

The third color filter CF3 may be to transmit the light of the third color therethrough. For example, the third color filter CF3 may be to transmit the light of the third color emitted from the third light emitting element EL3 and passing through the third light transmitting member TPL therethrough. Accordingly, the light of the third color may be emitted from the third emission area EA3. As an example, the third color filter CF3 may be a blue color filter, and the blue light may be emitted from the third emission area EA3.

Each of the first, second, and third color filters CF1, CF2, and CF3 may block or reduce external light incident from the outside. For example, the first color filter CF1 may increase purity (color purity) of a color corresponding to light of a first color, which is light of a red wavelength band, by blocking light of a second color, which is light of a green wavelength band, and light of third color, which is light of a blue wavelength band, that are incident from the outside.

The light blocking pattern LBP may overlap the bank BNK. The light blocking pattern LBP may be formed as a single-layer or multilayer light blocking layer.

In one or more embodiments, the light blocking pattern LBP may include the first color filter CF1, the second color filter CF2, and the third color filter CF3 that are arranged to overlap each other in the non-emission area NEA. As an example, the first color filter CF1, the second color filter CF2, and the third color filter CF3 arranged in the respective emission areas EA may extend to the non-emission area NEA to overlap each other, and may accordingly constitute the light blocking pattern LBP.

In one or more embodiments, the light blocking pattern LBP may include a black matrix pattern arranged in the non-emission area NEA. For example, the color filter layer CFL may include the respective color filters CF patterned to be individually separated from each other in the respective emission areas EA and a black matrix pattern arranged in the non-emission area NEA. At least a portion of the black matrix pattern may be arranged between adjacent color filters CF.

In one or more embodiments, the color filter layer CFL may further include a low refraction layer LRL covering one surface of each of the color filters CF. For example, the low refraction layer LRL may cover one surface of each of the color filters CF facing (e.g., opposite to) the light emitting element layer LEL and/or the like.

In one or more embodiments, the low refraction layer LRL may have a lower refractive index than the light transmitting members (e.g., the first light transmitting member WCL1, the second light transmitting member WCL2, and the third light transmitting member TPL) of the light conversion layer WCL. Accordingly, total (or increased) reflection of light traveling from the light transmitting members of the light conversion layer WCL to the low refraction layer LRL may be induced, such that the light may be recycled, and light efficiency of the pixels PX may be increased.

In one or more embodiments, a refractive index of the low refraction layer LRL may be 1.3 or less. When the refractive index of the low refraction layer LRL is 1.3 or less, a difference in refractive index between the light transmitting members of the light conversion layer WCL and the low refraction layer LRL is great, such that the total (or increased) reflection of the light may sufficiently occur. In one or more embodiments, the low refraction layer LRL may compensate for a step caused by the light blocking pattern LBP of the color filter layer CFL and may planarize a surface of the color filter layer CFL.

The protective layer PRL may be arranged on the substrate SUB and cover elements (e.g., the panel circuit layer PCL, the light emitting element layer LEL, the encapsulation layer ENL, the light conversion layer WCL, and/or the color filter layer CFL) arranged on the substrate SUB. In one or more embodiments, the protective layer PRL may be the upper substrate SUB2 on which the color filter layer CFL is formed.

The protective layer PRL may be a rigid or flexible substrate or film. In one or more embodiments, the protective layer PRL may include an insulating material such as glass, may have rigid characteristics, and may not be bent. In one or more embodiments, the protective layer PRL may include polyimide or other insulating materials, may have flexible characteristics so as to be capable of being deformed, for example, bent, folded, or rolled, and may or may not be bent.

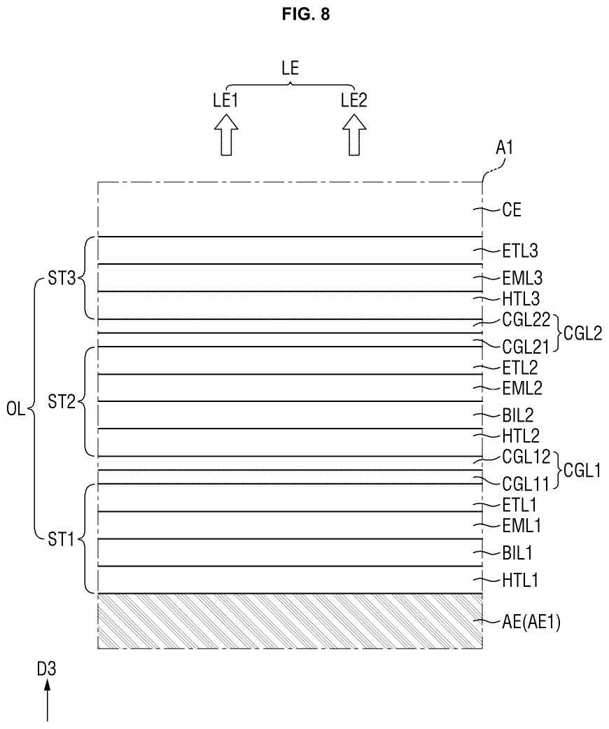

FIG. 8 is an enlarged view of area A1 of FIG. 5, according to one or more embodiments of the present disclosure. For example, FIG. 8 illustrates the light emitting layer OL according to one or more embodiments in more detail. While FIG. 8 illustrates the light emitting layer OL of the first light emitting element EL1 of FIG. 5, the below description may be equally applicable to the second light emitting element EL2 of FIG. 6 and/or the third light emitting element EL3 of FIG. 7.

Referring to FIGS. 5 to 8, the light emitting layer OL may have a structure in which a plurality of light emitting material layers are arranged to overlap each other, for example, a tandem structure. In one or more embodiments, the light emitting layer OL may include a first stack ST1 including a first light emitting material layer EML1, a second stack ST2 positioned on the first stack ST1 and including a second light emitting material layer EML2, a third stack ST3 positioned on the second stack ST2 and including a third light emitting material layer EML3, a first charge generating layer CGL1 positioned between the first stack ST1 and the second stack ST2, and a second charge generating layer CGL2 positioned between the second stack ST2 and the third stack ST3. The first stack ST1, the second stack ST2, and the third stack ST3 may overlap each other.

The first light emitting material layer EML1, the second light emitting material layer EML2, and the third light emitting material layer EML3 may overlap each other. In one or more embodiments, the first light emitting material layer EML1, the second light emitting material layer EML2, and the third light emitting material layer EML3 may all emit light of a third color, for example, blue light. As an example, each of the first light emitting material layer EML1, the second light emitting material layer EML2, and the third light emitting material layer EML3 may be a blue light emitting layer, and may include an organic material.

In one or more embodiments, at least one of the first light emitting material layer EML1, the second light emitting material layer EML2, and/or the third light emitting material layer EML3 may be to emit first blue light having a first peak wavelength, and at least another of the first light emitting material layer EML1, the second light emitting material layer EML2, and/or the third light emitting material layer EML3 may be to emit second blue light having a second peak wavelength different from the first peak wavelength. In one or more embodiments, at least one of the first light emitting material layer EML1, the second light emitting material layer EML2, and/or the third light emitting material layer EML3 may be to emit first blue light having a first peak wavelength, and the others of the first light emitting material layer EML1, the second light emitting material layer EML2, and/or the third light emitting material layer EML3 may be to emit second blue light having a second peak wavelength. For example, emitted light LE finally emitted from the light emitting layer OL may be mixed light in which a first component LE1 and a second component LE2 are mixed with each other, the first component LE1 may be the first blue light having the first peak wavelength, and the second component LE2 may be the second blue light having the second peak wavelength.

In one or more embodiments, a range of one of the first peak wavelength and the second peak wavelength may be about 440 nm or more and less than about 460 nm, and a range of the other of the first peak wavelength and/or the second peak wavelength may be about 460 nm or more and about 480 nm or less. However, the range of the first peak wavelength and the range of the second peak wavelength are not limited thereto. For example, both of the range of the first peak wavelength and the range of the second peak wavelength may also include about 460 nm. In one or more embodiments, any one of the first blue light and/or the second blue light may be light of a deep blue color, and the other of the first blue light and/or the second blue light may be light of a sky blue color.

In one or more embodiments, the emitted light LE emitted from the light emitting layer OL may be blue light, and may include a long-wavelength component and a short-wavelength component. Accordingly, the light emitting layer OL may be to emit blue light having a broader emission peak as the emitted light LE. Therefore, there is an advantage that color visibility at a side viewing angle may be improved compared to a display panel 100 using other light emitting elements emitting blue light having a sharper emission peak.

In one or more embodiments, each of the first light emitting material layer EML1, the second light emitting material layer EML2, and the third light emitting material layer EML3 may include a host and a dopant. The host may be tris(8-hydroxyquinolino)aluminum (Alq₃), 4,4′-bis(N-carbazolyl)-1,1′-biphenyl (CBP), poly(n-vinylcabazole) (PVK), 9,10-di(naphthalene-2-yl)anthracene (ADN), 4,4′,4″-tris(carbazol-9-yl)-triphenylamine (TCTA), 1,3,5-tris(N-phenylbenzimidazole-2-yl)benzene (TPBi), 3-tert-butyl-9,10-di(naphth-2-yl)anthracene (TBADN), distyryl arylene (DSA), 4,4′-bis(9-carbazolyl)-2,2″-dimethyl-biphenyl (CDBP), 2-methyl-9,10-bis(naphthalen-2-yl)anthracene (MADN), and/or the like, but the present disclosure is not limited thereto.

In one or more embodiments, each of the first light emitting material layer EML1, the second light emitting material layer EML2, and the third light emitting material layer EML3 may include a fluorescent material including any one selected from the group consisting of spiro-DPVBi, spiro-6P, distyryl-benzene (DSB), distyryl-arylene (DSA), a polyfluorene (PFO)-based polymer, and a poly(p-phenylene vinylene)-based polymer. In one or more embodiments, each of the first light emitting material layer EML1, the second light emitting material layer EML2, and the third light emitting material layer EML3 may include a phosphorescent material including an organometallic complex such as (4,6-F2ppy)2Irpic. The first light emitting material layer EML1, the second light emitting material layer EML2, and the third light emitting material layer EML3 may include materials other than the aforementioned materials.

As described above, at least one of the first light emitting material layer EML1, the second light emitting material layer EML2, and/or the third light emitting material layer EML3 emits blue light of a wavelength band different from that of at least another of the first light emitting material layer EML1, the second light emitting material layer EML2, and/or the third light emitting material layer EML3. In one or more embodiments, in order to emit blue light of different wavelength bands, the first light emitting material layer EML1, the second light emitting material layer EML2, and the third light emitting material layer EML3 may include the same material and a method of adjusting a resonance distance may be used. In one or more embodiments, in order to emit blue light of different wavelength bands, at least one of the first light emitting material layer EML1, the second light emitting material layer EML2, and/or the third light emitting material layer EML3 and at least another of the first light emitting material layer EML1, the second light emitting material layer EML2, and/or the third light emitting material layer EML3 may include different materials.

However, the present disclosure is not limited thereto. For example, the blue light emitted by each of the first light emitting material layer EML1, the second light emitting material layer EML2, and the third light emitting material layer EML3 may have a peak wavelength of about 440 nm to about 480 nm, and the first light emitting material layer EML1, the second light emitting material layer EML2, and the third light emitting material layer EML3 may be made of the same material.

In one or more embodiments, at least one of the first light emitting material layer EML1, the second light emitting material layer EML2, and/or the third light emitting material layer EML3 may be to emit first blue light having a first peak wavelength, another of the first light emitting material layer EML1, the second light emitting material layer EML2, and/or the third light emitting material layer EML3 may be to emit second blue light having a second peak wavelength different from the first peak wavelength, and the other of the first light emitting material layer EML1, the second light emitting material layer EML2, and/or the third light emitting material layer EML3 may be to emit third blue light having a third peak wavelength different from the first peak wavelength and the second peak wavelength.

In one or more embodiments, a range of any one of the first peak wavelength, the second peak wavelength, and/or the third peak wavelength may be about 440 nm or more and less than about 460 nm. A range of another of the first peak wavelength, the second peak wavelength, and/or the third peak wavelength may be about 460 nm or more and less than about 470 nm, and a range of the other of the first peak wavelength, the second peak wavelength, and/or the third peak wavelength may be about 470 nm or more and about 480 nm or less.

In one or more embodiments, the emitted light LE emitted from the light emitting layer OL may be blue light, and may include a long-wavelength component, a mid-wavelength component, and a short-wavelength component. Accordingly, the light emitting layer OL may be to emit blue light having a broader emission peak as the emitted light LE, and may improve color visibility at a side viewing angle of the display panel 110.

The light emitting element EL having the tandem structure described above has an advantage that light efficiency may be increased and an advantage that a lifespan of the display device 100 may be increased, compared to a light emitting element having a non-tandem structure.

In one or more embodiments, at least one of the first light emitting material layer EML1, the second light emitting material layer EML2, and/or the third light emitting material layer EML3 may be to emit the light of the third color, for example, blue light, and at least another of the first light emitting material layer EML1, the second light emitting material layer EML2, and/or the third light emitting material layer EML3 may be to emit the light of the second color, for example, green light. A range of a peak wavelength of the blue light emitted by at least one of the first light emitting material layer EML1, the second light emitting material layer EML2, and/or the third light emitting material layer EML3 may be about 440 nm or more to about 480 nm or less, or about 460 nm or more to about 480 nm or less. A range of a peak wavelength of the green light emitted by at least another of the first light emitting material layer EML1, the second light emitting material layer EML2, and/or the third light emitting material layer EML3 may be about 510 nm to about 550 nm.

As an example, any one of the first light emitting material layer EML1, the second light emitting material layer EML2, and/or the third light emitting material layer EML3 may be a green light emitting layer emitting the green light, and the others of the first light emitting material layer EML1, the second light emitting material layer EML2, and/or the third light emitting material layer EML3 may be blue light emitting layers emitting the blue light. If (e.g., when) the others of the first light emitting material layer EML1, the second light emitting material layer EML2, and/or the third light emitting material layer EML3 are the blue light emitting layers, ranges of peak wavelengths of the blue light emitted by the two blue light emitting layers may be the same as or different from each other.

In one or more embodiments, the emitted light LE emitted from the light emitting layer OL may be mixed light in which a first component LE1, which is blue light, and a second component LE2, which is green light, are mixed with each other. For example, if (e.g., when) the first component LE1 is light of a deep blue color and the second component LE2 is green light, the emitted light LE may be light of a sky blue color. Similar to the above-described embodiments, the emitted light LE emitted from the light emitting layer OL is mixed light of the blue light and the green light, and includes a long-wavelength component and a short-wavelength component.

Accordingly, the light emitting layer OL may be to emit blue light having a broader emission peak as the emitted light LE, and may improve color visibility at a side viewing angle. In one or more embodiments, if (e.g., when) the second component LE2 of the emitted light LE is the green light, a green light component of the light provided from the display device 100 to the outside may complement the blue light, and accordingly, color reproducibility of the display device 100 may be improved.

In one or more embodiments, the green light emitting layer of the first light emitting material layer EML1, the second light emitting material layer EML2, and/or the third light emitting material layer EML3 may include a host and a dopant. The host of the green light emitting layer may be tris(8-hydroxyquinolino)aluminum (Alq₃), 4,4′-bis(N-carbazolyl)-1,1′-biphenyl (CBP), poly(n-vinylcabazole) (PVK), 9,10-di(naphthalene-2-yl)anthracene (ADN), 4,4′,4″-tris(carbazol-9-yl)-triphenylamine (TCTA), 1,3,5-tris(N-phenylbenzimidazole-2-yl)benzene (TPBi), 3-tert-butyl-9,10-di(naphth-2-yl)anthracene (TBADN), distyryl arylene (DSA), 4,4′-bis(9-carbazolyl)-2,2″-dimethyl-biphenyl (CDBP), or 2-methyl-9,10-bis(naphthalen-2-yl)anthracene (MADN), but the present disclosure is not limited thereto. The dopant of the green light emitting layer may be a fluorescent material including tris-(8-hydroyquinolato) aluminum(Ill) (Alq₃) or a phosphorescent material, and may be fac tris(2-phenylpyridine)iridium (Ir(ppy)₃), bis(2-phenylpyridine)(acetylacetonate)iridium(Ill) (Ir(ppy)₂(acac)), tris[2-(p-tolyl)pyridine]iridium(Ill) (Ir(mppy)₃), and/or the like, but the present disclosure is not limited thereto.

The first charge generating layer CGL1 may be positioned between the first stack ST1 and the second stack ST2. The first charge generating layer CGL1 may inject charges into each light emitting layer OL. The first charge generating layer CGL1 may adjust charge balance between the first stack ST1 and the second stack ST2. The first charge generating layer CGL1 may include an n-type or kind charge generating layer CGL11 and a p-type or kind charge generating layer CGL12. The p-type or kind charge generating layer CGL12 may be arranged on the n-type or kind charge generating layer CGL11, and may be positioned between the n-type or kind charge generating layer CGL11 and the second stack ST2.

The first charge generating layer CGL1 may have a structure in which the n-type or kind charge generating layer CGL11 and the p-type or kind charge generating layer CGL12 are in contact with each other. The n-type or kind charge generating layer CGL11 may be more adjacent to the pixel electrode AE of the light emitting element EL than the p-type or kind charge generating layer CGL12 is. The p-type or kind charge generating layer CGL12 may be more adjacent to the common electrode CE of the light emitting element EL than the n-type or kind charge generating layer CGL11 is. The n-type or kind charge generating layer CGL11 may supply electrons to the first light emitting material layer EML1 adjacent to the pixel electrode AE, and the p-type or kind charge generating layer CGL12 may supply holes to the second light emitting material layer EML2 included in the second stack ST2. The first charge generating layer CGL1 may be arranged between the first stack ST1 and the second stack ST2 and provide charges to the light emitting material layers of the first and second stacks to increase luminous efficiency of the light emitting element EL and reduce a driving voltage of the light emitting element EL.

The first stack ST1 may be positioned on the pixel electrodes AE of the light emitting elements EL arranged in the emission areas EA. The first stack ST1 may further include a first hole transporting layer HTL1, a first electron blocking layer BIL1, and a first electron transporting layer ETL1.

The first hole transporting layer HTL1 may be positioned on the pixel electrodes AE of the light emitting elements EL. The first hole transporting layer HTL1 may facilitate transport of holes and include a hole transporting material. The hole transporting material may include carbazole-based derivatives such as N-phenylcarbazole and polyvinylcarbazole, fluorene-based derivatives, triphenylamine-based derivatives such as N,N′-bis(3-methylphenyl)-N,N′-diphenyl-[1,1-biphenyl]-4,4′-diamine (TPD) and 4,4′,4″-tris(N-carbazolyl)triphenylamine (TCTA), N,N′-di(1-naphthyl)-N,N′-diphenylbenzidine (NPB), 4.4′-cyclohexylidene bis[N,N-bis(4-methylphenyl)benzenamine](TAPC), and/or the like, but the present disclosure is not limited thereto.

The first electron blocking layer BIL1 may be positioned on the first hole transporting layer HTL1. For example, the first electron blocking layer BIL1 may be positioned between the first hole transporting layer HTL1 and the first light emitting material layer EML1. The first electron blocking layer BIL1 may include a hole transporting material and a metal or a metal compound so as to prevent or reduce the likelihood of electrons generated in the first light emitting material layer EML1 from crossing over into the first hole transporting layer HTL1. In one or more embodiments, each of the first hole transporting layer HTL1 and the first electron blocking layer BIL1 may also be formed as a single layer in which the respective materials are mixed with each other.

The first electron transporting layer ETL1 may be positioned on the first light emitting material layer EML1. For example, the first electron transporting layer ETL1 may be positioned between the first charge generating layer CGL1 and the first light emitting material layer EML1. In one or more embodiments, the first electron transporting layer ETL1 may include an electron transporting material such as tris(8-hydroxyquinolinato)aluminum (Alq₃), 1,3,5-tri(1-phenyl-1H-benzo[d]imidazol-2-yl)phenyl (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate (Bebq2), 9,10-di(naphthalene-2-yl)anthracene (ADN), and/or (e.g., suitable) mixtures thereof, but the electron transporting material is not limited thereto.

The second stack ST2 may be positioned on the first charge generating layer CGL1. The second stack ST2 may further include a second hole transporting layer HTL2, a second electron blocking layer BIL2, and a second electron transporting layer ETL2.

The second hole transporting layer HTL2 may be positioned on the first charge generating layer CGL1. The second hole transporting layer HTL2 may be made of substantially the same material as the first hole transporting layer HTL1 or may include one or more materials selected from among the materials listed as examples of the materials included in the first hole transporting layer HTL1. The second hole transporting layer HTL2 may be formed as a single layer or multiple layers.

The second electron blocking layer BIL2 may be positioned on the second hole transporting layer HTL2. For example, the second electron blocking layer BIL2 may be positioned between the second hole transporting layer HTL2 and the second light emitting material layer EML2. The second electron blocking layer BIL2 may be made of substantially the same material as the first electron blocking layer BIL1 and may have substantially the same structure as the first electron blocking layer BIL1 or may include one or more materials selected from among the materials listed as examples of the materials included in the first electron blocking layer BIL1.

The second electron transporting layer ETL2 may be positioned on the second light emitting material layer EML2. For example, the second electron transporting layer ETL2 may be positioned between the second charge generating layer CGL2 and the second light emitting material layer EML2. The second electron transporting layer ETL2 may be made of substantially the same material as the first electron transporting layer ETL1 and may have substantially the same structure as the first electron transporting layer ETL1 or may include one or more materials selected from among the materials listed as examples of the materials included in the first electron transporting layer ETL1. The second electron transporting layer ETL2 may be formed as a single layer or multiple layers.

The second charge generating layer CGL2 may be positioned on the second stack ST2. For example, the second charge generating layer CGL2 may be positioned between the second stack ST2 and the third stack ST3. The second charge generating layer CGL2 may have substantially the same structure as the first charge generating layer CGL1. For example, the second charge generating layer CGL2 may include an n-type or kind charge generating layer CGL21 and a p-type or kind charge generating layer CGL22. The p-type or kind charge generating layer CGL22 may be arranged on the n-type or kind charge generating layer CGL21.

The second charge generating layer CGL2 may have a structure in which the n-type or kind charge generating layer CGL21 and the p-type or kind charge generating layer CGL22 are in contact with each other. The first charge generating layer CGL1 and the second charge generating layer CGL2 may be made of substantially the same material or substantially different materials.

The third stack ST3 may be positioned on the second charge generating layer CGL2. The third stack ST3 may further include a third hole transporting layer HTL3 and a third electron transporting layer ETL3.

The third hole transporting layer HTL3 may be positioned on the second charge generating layer CGL2. The third hole transporting layer HTL3 may be made of substantially the same material as the first hole transporting layer HTL1 or may include one or more materials selected from among the materials listed as examples of the materials included in the first hole transporting layer HTL1. The third hole transporting layer HTL3 may be formed as a single layer or multiple layers. When the third hole transporting layer HTL3 is formed as the multiple layers, the respective layers may include substantially different materials.

The third electron transporting layer ETL3 may be positioned on the third light emitting material layer EML3. For example, the third electron transporting layer ETL3 may be positioned between the common electrode CE of the light emitting element EL and the third light emitting material layer EML3. The third electron transporting layer ETL3 may be made of substantially the same material as the first electron transporting layer ETL1 and may have substantially the same structure as the first electron transporting layer ETL1 or may include one or more materials selected from among the materials listed as examples of the materials included in the first electron transporting layer ETL1. The third electron transporting layer ETL3 may be formed as a single layer or multiple layers. When the third electron transporting layer ETL3 is formed as the multiple layers, the respective layers may include substantially different materials.

In one or more embodiments, a hole injection layer may be further positioned between the pixel electrode AE of each of the light emitting elements EL and the first stack ST1, between the first charge generating layer CGL1 and the second stack ST2, or between the second charge generating layer CGL2 and the third stack ST3. The hole injection layer may serve to more smoothly inject holes into the first light emitting material layer EML1, the second light emitting material layer EML2, and/or the third light emitting material layer EML3. In one or more embodiments, the hole injection layer may be made of one or more selected from the group consisting of cupper phthalocyanine (CuPc), poly(3,4)-ethylenedioxythiophene (PEDOT), polyaniline (PANI), and N,N-dinaphthyl-N,N′-diphenyl benzidine (NPD), but the present disclosure is not limited thereto.

In one or more embodiments, an electron injection layer may be further positioned between the first stack ST1 and the first charge generating layer CGL1, between the second stack ST2 and the second charge generating layer CGL2, or between the third electron transporting layer ETL3 and the common electrode CE of the light emitting elements EL. The electron injection layer may serve to smoothly inject electrons, and may be made of tris(8-hydroxyquinolino)aluminum (Alq₃), PBD, TAZ, spiro-PBD, BAlq, or SAlq, but the present disclosure is not limited thereto. In one or more embodiments, the electron injection layer may include a metal halide compound, for example, one or more selected from the group consisting of MgF₂, LiF, NaF, KF, RbF, CsF, FrF, LiI, NaI, KI, RbI, CsI, FrI, and CaF₂, but the present disclosure is not limited thereto. In one or more embodiments, the electron injection layer may include a lanthanum-based material such as Yb, Sm, or Eu. In one or more embodiments, the electron injection layer may include both a metal halide material and a lanthanum-based material such as RbI:Yb or KI:Yb. When the electron injection layer includes both the metal halide material and the lanthanum-based material, the electron injection layer may be formed by co-depositing the metal halide material and the lanthanum-based material.

In one or more embodiments, the light emitting layer OL may not include a (e.g., may exclude any) red light emitting material layer, and accordingly, may not emit the light of the third color such as red light. For example, the emitted light LE may not include a (e.g., may exclude any) light component having a peak wavelength in the range of about 610 nm to about 650 nm, and may include only a light component having a peak wavelength in the range of about 440 nm to about 550 nm.

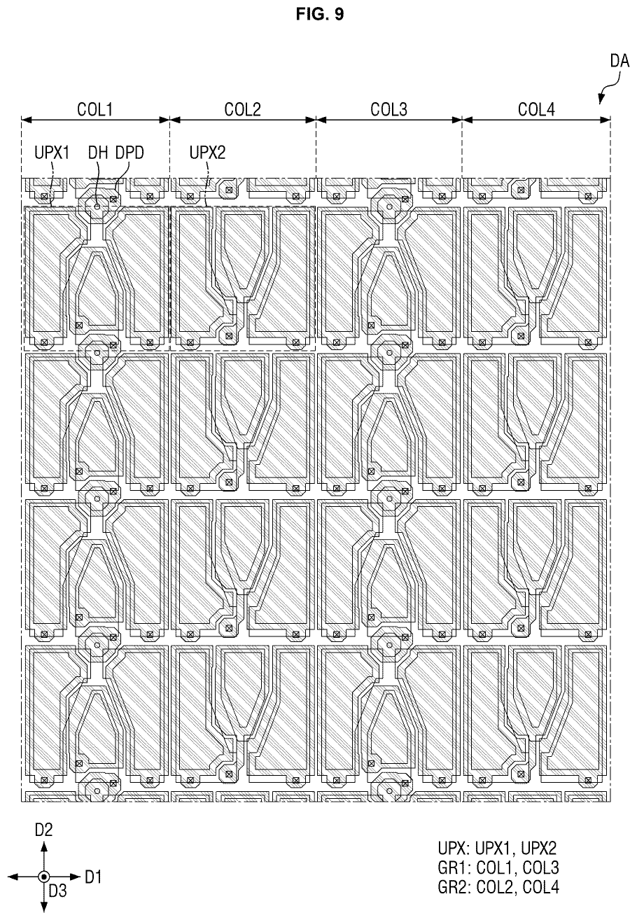

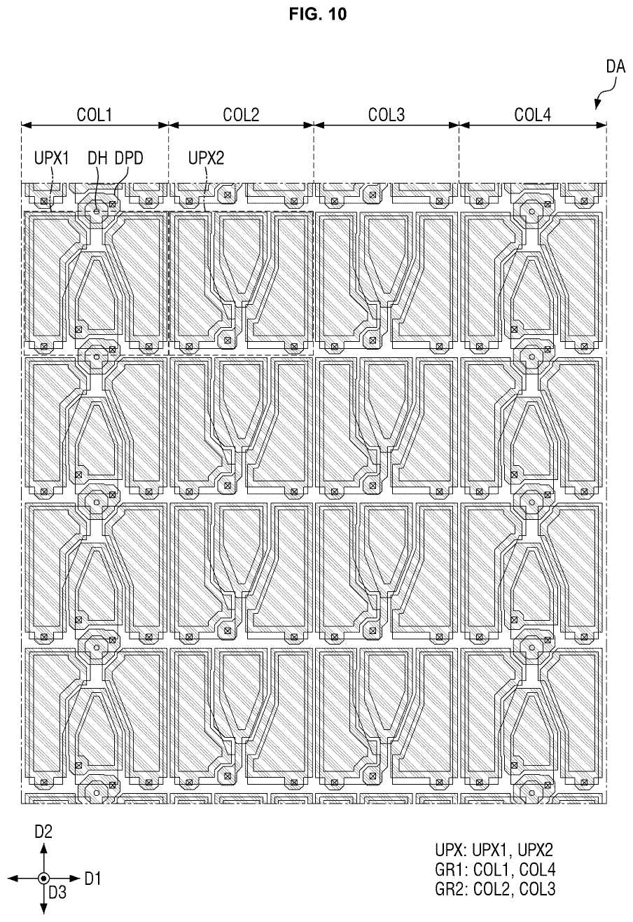

FIG. 9 is a plan view illustrating a portion of a display area DA according to one or more embodiments of the present disclosure. FIG. 10 is a plan view illustrating a portion of a display area DA according to one or more embodiments of the present disclosure. For example, FIGS. 9 and 10 illustrate a portion of a display area DA where four pixel columns COL adjacent to each other are arranged, and illustrate different embodiments in relation to an arrangement cycle of a first group of pixel columns GR1 and a second group of pixel columns GR2.

Referring to FIGS. 9 and 10 in addition to FIG. 4, the display area DA may include a first group of pixel columns GR1 and a second group of pixel columns GR2 that include unit pixels UPX having different forms. For example, the first group of pixel columns GR1 may include a first column COL1, and each of the first group of pixel columns GR1 may have substantially the same form as the first column COL1. The second group of pixel columns GR2 may include a second column COL2, and each of the second group of pixel columns GR2 may have substantially the same form as the second column COL2. That is, the first group of pixel columns GR1 may include a first column COL1, with each column in this group having substantially the same form as COL1. Similarly, the second group of pixel columns GR2 may include a second column COL2, with each column in this group having substantially the same form as COL2.

In each unit pixel area positioned in the first group of pixel columns GR1, a first emission area EA1, a second emission area EA2, and a third emission area EA3 may be arranged in substantially the same structure as the first unit pixel UPX1. That is, in each unit pixel area UPX within the first group of pixel columns GR1, the first emission area EA1, second emission area EA2, and third emission area EA3 may be arranged in substantially the same structure as the first unit pixel UPX1. In addition, in each unit pixel area positioned in the first group of pixel columns GR1, a first pixel electrode AE1, a second pixel electrode AE2, and a third pixel electrode AE3 may be arranged in substantially the same structure as the first unit pixel UPX1. That is, in each unit pixel area UPX within the first group of pixel columns GR1, the first pixel electrode AE1, second pixel electrode AE2, and third pixel electrode AE3 may be arranged in substantially the same structure as the first unit pixel UPX1.

Each of the first group of pixel columns GR1 may include at least one pad electrode DPD. For example, each of the first group of pixel columns GR1 may include a plurality of pad electrodes DPD arranged between unit pixels UPX adjacent to each other in the second direction D2.

In each unit pixel area positioned in the second group of pixel columns GR2, a first emission area EA1, a second emission area EA2, and a third emission area EA3 may be arranged in substantially the same structure as the second unit pixel UPX2. In one or more embodiments, in each unit pixel area positioned in the second group of pixel columns GR2, a first pixel electrode AE1, a second pixel electrode AE2, and a third pixel electrode AE3 may be arranged in substantially the same structure as the second unit pixel UPX2. The second group of pixel columns GR2 may not include (e.g., may exclude) the pad electrode DPD.

The first group of pixel columns GR1 may be arranged in the display area DA every N pixel columns (where N is a natural number of 2 or more). The second group of pixel columns GR2 may be arranged between the first group of pixel columns GR1.

In one or more embodiments, the first group of pixel columns GR1 may be arranged in the display area DA every two pixel columns, as illustrated in FIG. 9. For example, the first group of pixel columns GR1 and the second group of pixel columns GR2 may be alternately arranged in the display area DA along the first direction D1. As an example, odd-numbered pixel columns of the display area DA including a first column COL1 and a third column COL3 may be configured as the first group of pixel columns GR1, and even-numbered pixel columns of the display area DA including a second column COL2 and a fourth column COL4 may be configured as the second group of pixel columns GR2. In one or more embodiments, odd-numbered pixel columns of the display area DA may be configured as the second group of pixel columns GR2, and even-numbered pixel columns of the display area DA may be configured as the first group of pixel columns GR1.

In one or more embodiments, the first group of pixel columns GR1 may be arranged in the display area DA every three pixel columns, as illustrated in FIG. 10. As an example, the first group of pixel columns GR1 and the second group of pixel columns GR2 may be alternately arranged in the display area DA in the ratio of approximately 1:2.

In addition to the embodiments illustrated in FIGS. 9 and 10, an arrangement cycle (pattern), a ratio, and/or the like, of the first group of pixel columns GR1 and the second group of pixel columns GR2 may be variously changed according to one or more embodiments. In one or more embodiments, an arrangement cycle and/or the like of the pad electrodes DPD and/or the drilling holes DH arranged in each of the first group of pixel columns GR1 may also be variously changed according to one or more embodiments.

With the display device 100 according to the above-described embodiments, by efficiently disposing the emission areas EA (or the pixel electrodes AE arranged in the emission areas EA) of the unit pixels UPX and the pad electrodes DPD, space consumption due to the pad electrodes DPD may be reduced, minimized, or reduced, and the pad electrodes DPD and the pixel electrodes AE may be arranged closer to each other. Accordingly, light emitting areas (e.g., sizes of the emission areas EA of the pixels PX) or aperture ratios (e.g., areas of light transmitting areas of the color filter layer CFL corresponding to the emission areas EA of the pixels PX or aperture ratios of the color filter layer CFL) of the pixels PX may be improved, and a space utilization rate and light efficiency of the display device 100 may be improved.

In one or more embodiments, with the display device 100, edge portions including only the first emission areas EA1 and the second emission areas EA2 of the unit pixels UPX (e.g., the first edge portion EDG1 of the first unit pixel UPX1 and the fourth edge portion EDG4 of the second unit pixel UPX2) may be staggered or alternately arranged. For example, in each unit pixel UPX, only the first emission area EA1 and the second emission area EA2 of each unit pixel UPX may be exposed at one of the edge portions positioned at both ends (e.g., opposite ends) of each unit pixel UPX in the second direction D2, and the first emission area EA1, the second emission area EA2, and the third emission area EA3 of each unit pixel UPX may all be exposed at the other of the edge portions. In one or more embodiments, around (adjacent) the edge portion where only the first emission area EA1 and the second emission area EA2 of each unit pixel UPX are exposed, an edge portion of an adjacent unit pixel UPX where a first emission area EA1, a second emission area EA2, and a third emission area EA3 are all exposed may be arranged. Accordingly, the emission areas EA of the respective colors may be relatively evenly arranged at upper edge portions, lower edge portions, and/or the like, of pixel rows throughout the display area DA. Accordingly, a color fringing or color jamming phenomenon in which patterns of a specific color (e.g., horizontal line patterns of a specific color) are viewed along the upper edge portions or the lower edge portions of the pixel rows may be prevented, minimized, or reduced. As an example, if (e.g., when) a box pattern of a full white color having a set or predetermined size is displayed on a background of a full black color, the color fringing or color jamming phenomenon may be confirmed at an upper edge portion, a lower edge portion, and/or the like, of the box pattern. In the display device 100 according to one or more embodiments, such a color fringing or color jamming phenomenon may be prevented, minimized, or reduced. As an example, the display device 100 according to one or more embodiments may have a color fringing or color jamming index less than 1 at each of the upper edge portion and the lower edge portion.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

Further, the use of “may” when describing embodiments of the present disclosure refers to “one or more embodiments of the present disclosure.”

As used herein, the term “substantially,” “about,” and similar terms are used as terms of approximation and not as terms of degree, and are intended to account for the inherent deviations in measured or calculated values that would be recognized by those of ordinary skill in the art. “Substantially” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially” may mean within one or more standard deviations, or within ±30%, 20%, 10%, 5% of the stated value.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The display device, electronic apparatus or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. It is to be understood that the foregoing is an illustration of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device comprising:
a display area comprising unit pixels each comprising a first emission area, a second emission area, and a third emission area;
a first unit pixel of the unit pixels in a first column of the display area; and
a second unit pixel of the unit pixels in a second column of the display area and adjacent to the first unit pixel in a first direction,
wherein at a first edge portion at one end of the first unit pixel in a second direction crossing the first direction, only the first emission area and the second emission area selected from among the first emission area, the second emission area, and the third emission area of the first unit pixel are positioned, and
at a second edge portion adjacent to the first edge portion in the first direction and at one end of the second unit pixel in the second direction, the first emission area, the second emission area, and the third emission area of the second unit pixel are positioned.

2. The display device of claim 1, wherein at a third edge portion at an opposite end of the first unit pixel relative to the one end of the first unit pixel in the second direction, the first emission area, the second emission area, and the third emission area of the first unit pixel are arranged.

3. The display device of claim 2, wherein the first column of the display area comprises a first pad electrode at the first edge portion.

4. The display device of claim 3, wherein each of the unit pixels comprises a first pixel electrode in the first emission area, a second pixel electrode in the second emission area, and a third pixel electrode in the third emission area, and
the first pad electrode is between the first pixel electrode and the second pixel electrode of the first unit pixel at the first edge portion.

5. The display device of claim 4, wherein the first pad electrode overlaps the first emission area and the second emission area of the first unit pixel at the first edge portion.

6. The display device of claim 4, wherein a size of the third emission area is smaller than a size of each of the first emission area and the second emission area, and
in a unit pixel area of the first unit pixel, the third emission area is at a position spaced from the first edge portion.

7. The display device of claim 4, wherein each of the unit pixels further comprises a light emitting layer and a common electrode that are on each of the first pixel electrode, the second pixel electrode, and the third pixel electrode, and
the common electrode is electrically connected to the first pad electrode through a drilling hole at the first pad electrode.

8. The display device of claim 7, wherein the common electrode is along an entirety of the display area, and
the drilling hole penetrates through the light emitting layer on the first pad electrode.

9. The display device of claim 7, further comprising a power line which is electrically connected to the first pad electrode and to which a common voltage is applied.

10. The display device of claim 4, wherein at a fourth edge portion adjacent to the third edge portion in the first direction and at an opposite end of the second unit pixel relative to the one end of the second unit pixel in the second direction, only the first emission area and the second emission area selected from among the first emission area, the second emission area, and the third emission area of the second unit pixel are arranged.

11. The display device of claim 10, wherein the first pixel electrode, the second pixel electrode, and the third pixel electrode of the second unit pixel are electrically connected to respective pixel circuits through respective connection holes positioned at the fourth edge portion.

12. The display device of claim 3, wherein the first column of the display area further comprises a second pad electrode at the third edge portion.

13. The display device of claim 12, wherein the second pad electrode is between the first emission area and the second emission area of the first unit pixel and overlaps the third emission area of the first unit pixel at the third edge portion.

14. The display device of claim 2, wherein each of the first column and the second column comprises a plurality of the unit pixels, and
wherein the display area further comprises:
a first group of pixel columns which comprises the first column and in which each first emission area, second emission area, and third emission area have substantially the same structure as the first unit pixel; and
a second group of pixel columns which comprises the second column and in which each first emission area, second emission area, and third emission area have substantially the same structure as the second unit pixel.

15. The display device of claim 14, wherein the first group of pixel columns are arranged in the display area every N pixel columns (where N is a natural number of 2 or more), and
the second group of pixel columns are between the first group of pixel columns.

16. The display device of claim 14, wherein the first group of pixel columns and the second group of pixel columns are alternately arranged in the display area along the first direction.

17. The display device of claim 14, wherein the display area further comprises a plurality of pad electrodes in the first group of pixel columns.

18. The display device of claim 17, wherein the second group of pixel columns do not comprise the pad electrodes.

19. The display device of claim 1, wherein the first emission area is a red emission area emitting red light,
the second emission area is a green emission area emitting green light, and
the third emission area is a blue emission area emitting blue light.

20. The display device of claim 1, wherein the first direction is a transverse direction of the display area, and
the second direction is a longitudinal direction of the display area.

21. An electronic device including a display device, the display device comprising:
a display area comprising unit pixels each comprising a first emission area, a second emission area, and a third emission area;
a first unit pixel of the unit pixels in a first column of the display area; and
a second unit pixel of the unit pixels in a second column of the display area and adjacent to the first unit pixel in a first direction,
wherein at a first edge portion at one end of the first unit pixel in a second direction crossing the first direction, only the first emission area and the second emission area selected from among the first emission area, the second emission area, and the third emission area of the first unit pixel are positioned, and
at a second edge portion adjacent to the first edge portion in the first direction and at one end of the second unit pixel in the second direction, the first emission area, the second emission area, and the third emission area of the second unit pixel are positioned.
